(19) United States
(12) Patent Application Publication
(10) Pub. No.: US 2024/0416578 A1
(43) Pub. Date: Dec. 19, 2024

(54) LAYER FORMING COMPOSITION, FILM FORMING METHOD, AND ARTICLE MANUFACTURING METHOD

(71) Applicant: CANON KABUSHIKI KAISHA, Tokyo (JP)

(72) Inventors: HINAKO MATSUSHIMA, Tochigi (JP); HIDEKI IMAMURA, Tochigi (JP); Tomonori Otani, Fukui (JP); MASAKI ISHIDA, Tochigi (JP); TOSHIKI ITO, Kanagawa (JP)

(21) Appl. No.: 18/739,535

(22) Filed: Jun. 11, 2024

(30) Foreign Application Priority Data
Jun. 15, 2023 (JP) 2023-098730

(51) Int. Cl. B29C 59/02; B29C 35/08; B29K 105/00; B29L 31/34; C08K 5/053; C08K 5/06; C08K 5/3492

(52) U.S. Cl. CPC B29C 59/026; B29C 35/0805; B29C 59/022; C08K 5/053; C08K 5/06; C08K 5/34922; B29C 2035/0827; B29K 2105/0097; B29L 2031/34

(57) ABSTRACT

The present invention provides a layer forming composition used to form an adhesion layer that brings a base material and a curable composition into tight contact with each other, comprising a surfactant (D) whose HLB value is 1 to 5.

### BACKGROUND OF THE INVENTION

### Field of the Invention

The present invention relates to a layer forming composition, a film forming method, and an article manufacturing method.

### Description of the Related Art

As a technique for manufacturing an article with a microstructure such as a semiconductor device or MEMS, an imprint technique has received attention. In the imprint technique, in a state in which a mold with a fine concave-convex pattern formed on the surface is pressed against a curable composition (resist) supplied onto a base material, the curable composition is cured. Thus, a cured film of the curable composition to which the concave-convex pattern of the mold is transferred is formed on the base material. According to the imprint technique, a fine structure on a several nanometer order can be formed on a base material.

A pattern forming method using the imprint technique can include an arranging step, a contact step, a curing step, and a mold separation step. In the arranging step, a curable composition is arranged on a pattern forming region of a base material. In the contact step, a mold with a concave-convex pattern formed is brought into contact with curable composition on the base material, thereby molding the curable composition. In the curing step, for example, the curable composition is irradiated with light to cure the curable composition, thereby forming a cured product on the base material. In the mold separation step, the mold is separated from the cured product of the curable composition. By executing these steps, a cured film to which the pattern of the mold is transferred is formed on the base material.

In the pattern forming method using the imprint technique (particularly, the mold separation step), adhesion between the curable composition and the base material is important. In a case where the adhesion between the curable composition and the base material is low, when separating the mold from the cured product of the curable composition in the mold separation step, the mold to which a part of the cured product remains adhered may be peeled from the base material, and a part of the pattern that should be formed on the cured product may be chipped.

As a technique for improving the adhesion between the curable composition and the base material, there is proposed a technique of forming, between the curable composition and the base material, an adhesion layer that is a layer configured to make the curable composition and the base material adhere (Japanese Patent Laid-Open No. 2013-202982).

In a case where defects exist in the adhesion layer itself formed on the base material, unfilling defects or film thickness unevenness may occur in the cured film of the curable composition formed on the base material (adhesion layer) by the imprint technique because of the defects in the adhesion layer. The unfilling defects may occur when the curable composition is cured in a state in which concave portions of the pattern of the mold are not sufficiently filled with the curable composition. The film thickness unevenness means unevenness of the film thickness of the cured film of the curable composition, and may occur, for example, in a case where the mold and the base material are not parallel because of defects existing in the adhesion layer itself, or in a case where the mold is deformed. Also, in a case where defects exist in the adhesion layer, the mold may permanently deform or the mold may break when the mold is brought into contact with the curable composition on the adhesion layer. Such defects in the adhesion layer are considered to be derived from a material (layer forming composition) used to form the adhesion layer and a layer forming composition capable of reducing defects in the adhesion layer is demanded in the imprint technique.

### SUMMARY OF THE INVENTION

The present invention provides, for example, a layer forming composition capable of forming a low-defect adhesion layer.

According to one aspect of the present invention, there is provided a layer forming composition used to form an adhesion layer that brings a base material and a curable composition into tight contact with each other, comprising a surfactant (D) whose HLB value is 1 to 5.

Further features of the present invention will become apparent from the following description of exemplary embodiments with reference to the attached drawings.

### BRIEF DESCRIPTION OF THE DRAWINGS

FIGURE is a view for explaining a film forming method and an article manufacturing method.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made an invention that requires all such features, and multiple such features may be combined as appropriate. Furthermore, in the attached drawings, the same reference numerals are given to the same or similar configurations, and redundant description thereof is omitted.

An adhesion layer forming composition 100 (layer forming composition) according to this embodiment is a composition used to form an adhesion layer 101 between a base material 102 (substrate) and a curable composition 103. The adhesion layer forming composition 100 contains at least a compound (A) having at least one functional group to be bonded to a base material 102 and at least one polymerizable functional group, a cross-linker (B), and a solvent (C). Also, the adhesion layer forming composition 100 contains a surfactant (D) whose HLB value is 1 to 5. Here, “making the base material 102 and the curable composition 103 adhere” can be defined as a state in which, in the mold separation step, the base material 102 and the cured film are bonded via the adhesion layer 101 with a strength stronger than a force for separating a mold from the cured film of the curable composition 103. As will be described later, the mold separation step is a step of separating the mold from the cured film of the curable composition 103 formed on the base material 102 in imprint processing.

The adhesion layer forming composition 100 according to this embodiment is particularly preferably used when forming a cured film (cured product) of the curable composition 103 on the base material. Also, a multilayered body including the base material 102 and the adhesion layer 101 formed by the adhesion layer forming composition 100 according to this embodiment can preferably be used as a base material on which the curable composition 103 is arranged (supplied) to obtain a cured film 109. Also, the adhesion layer forming composition 100 according to this embodiment can be used as an adhesion layer forming composition for imprint, and is particularly useful as an adhesion layer forming composition for photo-nanoimprint. Here, in this embodiment, an example in which a photocurable composition having a property of curing upon light irradiation is used as the curable composition 103 will be described. However, the curable composition 103 is not limited to the photocurable composition, and a thermally curable composition having a property of curing upon heating may be used.

Components of the adhesion layer forming composition 100 according to this embodiment will be described below in detail. The adhesion layer forming composition 100 according to this embodiment contains the compound (A), the cross-linker (B), the solvent (C), and the surfactant (D), as described above.

### <Compound (A)>

The compound (A) has at least one functional group to be bonded to the base material 102, and at least one polymerizable functional group to be bonded to the curable composition 103. Here, “functional group to be bonded” indicates a functional group that causes a chemical bond such as a covalent bond, an ionic bond, a hydrogen bond, or an intermolecular force. In a case where the whole adhesion layer forming composition 100 is defined as 100 mass %, the compound (A) is contained at a ratio less than 1 mass %. As for the type of the compound (A) usable in this embodiment, known compounds can widely be employed, and the type is not particularly limited.

The compound (A) according to this embodiment has, in one molecule, at least one of a hydroxyl group, a carboxyl group, a thiol group, an amino group, an epoxy group, and a (block) isocyanate group. Examples of the compound (A) are a compound having an ethylenically unsaturated bond containing group, a compound having an epoxy group, and a compound having a vinyl ether group.

Detailed examples of the compound (A) having an ethylenically unsaturated bond containing group are methyl (meth)acrylate, ethyl (meth)acrylate, butyl (meth)acrylate, N-vinyl-pyrrolidinone, 2-acryloyloxyethyl phthalate, 2-acryloyloxy 2-hydroxyethyl phthalate, 2-acryloyloxyethyl hexahydrophthalate, 2-acryloyloxypropyl phthalate, 2-ethyl-2-butyl propanediol acrylate, 2-ethylhexyl (meth)acrylate, 2-ethylhexylcarbitol (meth)acrylate, 2-hydroxybutyl (meth)acrylate, 2-hydroxyethyl (meth)acrylate, 2-hydroxypropyl (meth)acrylate, 4-hydroxybutyl (meth)acrylate, acrylic acid dimer, benzyl (meth)acrylate, 1- or 2-naphthyl (meth)acrylate, butoxyethyl (meth)acrylate, cetyl (meth)acrylate, ethylene oxide-modified (to be referred to as “EO” hereinafter) cresol (meth)acrylate, dipropylene glycol (meth)acrylate, ethoxylated phenyl (meth)acrylate, isooctyl (meth)acrylate, cyclohexyl (meth)acrylate, isobornyl (meth)acrylate, dicyclopentanyl (meth)acrylate, dicyclopentenyloxyethyl (meth)acrylate, isomyristyl (meth)acrylate, lauryl (meth)acrylate, methoxydipropylene glycol (meth)acrylate, methoxytripropylene glycol (meth)acrylate, methoxypolyethylene glycol (meth)acrylate, methoxytriethylene glycol (meth)acrylate, neopentyl glycol benzoate (meth)acrylate, nonyl phenylpolyethylene glycol (meth)acrylate, nonyl phenoxypolypropylene glycol (meth)acrylate, octyl (meth)acrylate, paracumyl phenoxymethylene glycol (meth)acrylate, epichlorohydrin (to be referred to as “ECH” hereinafter)-modified phenoxyacrylate, phenoxyethyl (meth)acrylate, phenoxydiethylene glycol (meth)acrylate, phenoxyhexaethylene glycol (meth)acrylate, phenoxytetraethylene glycol (meth)acrylate, polyethylene glycol (meth)acrylate, polyethylene glycol-polypropylene glycol (meth)acrylate, polypropylene glycol (meth)acrylate, stearyl (meth)acrylate, EO-modified succinic acid (meth)acrylate, tribromophenyl (meth)acrylate, EO-modified tribromophenyl (meth)acrylate, tridodecyl (meth)acrylate, p-isopropenylphenol, N-vinylpyrrolidone, N-vinylcaprolactam, diethylene glycol monoethyl ether (meth)acrylate, dimethyloldicyclopentane di(meth)acrylate, di(meth)acryloyl isocyanurate, 1,3-butylene glycol di(meth)acrylate, 1,4-butanediol di(meth)acrylate, EO-modified 1,6-hexanediol di(meth)acrylate, ECH-modified 1,6-hexanediol di(meth)acrylate, allyloxypolyethylene glycol acrylate, 1,9-nonanediol di(meth)acrylate, EO-modified bisphenol A di(meth)acrylate, PO-modified bisphenol A di(meth)acrylate, modified bisphenol A di(meth)acrylate, EO-modified bisphenol F di(meth)acrylate, ECH-modified hexahydrophthalic acid diacrylate, hydroxypivalic acid neopentyl glycol di(meth)acrylate, neopentyl glycol di(meth)acrylate, EO-modified neopentyl glycol diacrylate, propylene oxide (to be referred to as “PO” hereinafter)-modified neopentyl glycol diacrylate, caprolactone-modified hydroxypivalate neopentyl glycol, stearic acid-modified pentaerythritol di(meth)acrylate, ECH-modified phthalic acid di(meth)acrylate, poly(ethylene glycol-tetramethylene glycol) di(meth)acrylate, poly(propylene glycol-tetramethylene glycol) di(meth)acrylate, polyester (di)acrylate, polyethylene glycol di(meth)acrylate, polypropylene glycol di(meth)acrylate, ECH-modified propylene glycol di(meth)acrylate, silicone di(meth)acrylate, triethylene glycol di(meth)acrylate, tetraethylene glycol di(meth)acrylate, dimethyloltricyclodecane di(meth)acrylate, neopentyl glycol-modified trimethylolpropane di(meth)acrylate, tripropylene glycol di(meth)acrylate, EO-modified tripropylene glycol di(meth)acrylate, triglycerol di(meth)acrylate, dipropylene glycol di(meth)acrylate, divinyl ethylene urea, divinyl propylene urea, o-,m-,p-xylylene di(meth)acrylate, 1,3-adamantane diacrylate, norbornane dimethanol di(meth)acrylate, tricyclodecane dimethanol di(meth)acrylate, ECH-modified glycerol tri(meth)acrylate, EO-modified glycerol tri(meth)acrylate, PO-modified glycerol tri(meth)acrylate, pentaerythritol triacrylate, EO-modified phosphoric acid triacrylate, trimethylolpropane tri(meth)acrylate, caprolactone-modified trimethylolpropane tri(meth)acrylate, EO-modified trimethylolpropane tri(meth)acrylate, PO-modified trimethylolpropane tri(meth)acrylate, tris(acryloxyethyl)isocyanurate, dipentaerythritol hexa(meth)acrylate, caprolactone-modified dipentaerythritol hexa(meth)acrylate, dipentaerythritol hydroxypenta(meth)acrylate, alkyl-modified dipentaerythritol penta (meth)acrylate, dipentaerythritol poly(meth)acrylate, alkyl-modified dipentaerythritol tri(meth)acrylate, ditrimethylolpropane tetra(meth)acrylate, pentaerythritol ethoxytetra(meth)acrylate, and pentaerythritol tetra(meth)acrylate.

Examples of the compound (A) having an epoxy group are polyglycidyl ethers of polyether polyols obtained by adding one type or two types of alkylene oxides to aliphatic polyhydric alcohols such as bisphenol A diglycidyl ether, bisphenol F diglycidyl ether, bisphenol S diglycidyl ether, brominated Bisphenol A diglycidyl ether, brominated Bisphenol F diglycidyl ether, brominated bisphenol S diglycidyl ether, hydrogenated Bisphenol A diglycidyl ether, hydrogenated bisphenol F diglycidyl ether, hydrogenated bisphenol S diglycidyl ether, 1,4-butanediol diglycidyl ether, 1,6-hexanediol diglycidyl ether, glycerin triglycidyl ether, trimethylolpropane triglycidyl ether, polyethylene glycol diglycidyl ether, polypropylene glycol diglycidyl ether, ethylene glycol, propylene glycol, and glycerin, diglycidyl esters of aliphatic long-chain dibasic acids, monoglycidyl ethers of aliphatic higher alcohols, phenol, cresol, butyl phenol, or monoglycidyl ethers of polyether alcohol obtained by adding alkylene oxide to these, and blycidyl esters of higher fatty acids.

Examples of the compound having a vinyl ether group are 2-ethylhexyl vinyl ether, butanediol-1,4-divinyl ether, diethylene glycol monovinyl ether, diethylene glycol monovinyl ether, ethylene glycol divinyl ether, triethylene glycol divinyl ether, 1,2-propanediol divinyl ether, 1,3-propanediol divinyl ether, 1,3-butanediol divinyl ether, 1,4-butanediol divinyl ether, tetramethylene glycol divinyl ether, neopentyl glycol divinyl ether, trimethylolpropane trivinyl ether, trimethylolethane tri vinyl ether, hexanediol divinyl ether, tetraethylene glycol divinyl ether, pentaerythritol divinyl ether, pentaerythritol trivinyl ether, pentaerythritol tetra vinyl ether, sorbitol tetra vinyl ether, sorbitol penta-vinyl ether, ethylene glycol diethylene vinyl ether, triethylene glycol diethylene vinyl ether, ethylene glycol dipropylene vinyl ether, triethylene glycol diethylene vinyl ether, trimethylolpropane triethylene vinyl ether, trimethylolpropane diethylene vinyl ether, pentaerythritol diethylene vinyl ether, pentaerythritol triethylene vinyl ether, pentaerythritol tetraethylene vinyl ether, 1,1,1-tris [4-(2-vinyloxyethoxy)phenyl]ethane, bisphenol A divinyloxyethyl ether.

As an example, a poly(meth)acrylate compound having an ethylenically unsaturated group (P) and a hydrophilic group (Q) is preferable. Examples of the ethylenically unsaturated group (P) are a (meth)acryloyloxy group, a (meth)acryloylamino group, a maleimide group, an allyl group, and a vinyl group. Note that in this specification, a (meth)acryloyl group means an acryloyl group or a methacryloyl group having an alcohol residue equivalent to that. Examples of the hydrophilic group (Q) are an alcoholic hydroxyl group, a carboxyl group, a phenolic hydroxyl group, an ether group (preferably, a polyoxyalkylene group), an amino group, an amide group, an imide group, a ureido group, a urethane group, a cyano group, a sulfonamide group, a lactone group, and a cyclocarbonate group. In a case where the hydrophilic group is a urethane group, a group adjacent to the urethane group preferably exists as an oxygen atom, for example, “—O—C(═O)—NH—” in a resin.

A poly(meth)acrylate compound (acrylic resin) may include a repeating unit including the ethylenically unsaturated group (P) and a repeating unit including the hydrophilic group (Q) in the same repeating unit or different repeating units. However, the poly(meth)acrylate compound (acrylic resin) preferably includes these repeating units at a ratio of 20 to 100 mol %. Also, the poly(meth)acrylate compound (acrylic resin) may include another repeating unit that includes neither the ethylenically unsaturated group (P) nor the hydrophilic group (Q), and the ratio of the other repeating units is preferably 50 mol % or less in the acrylic resin.

The poly(meth)acrylate compound (acrylic resin) preferably includes repeating units represented by general formulas (I) and (II) below.

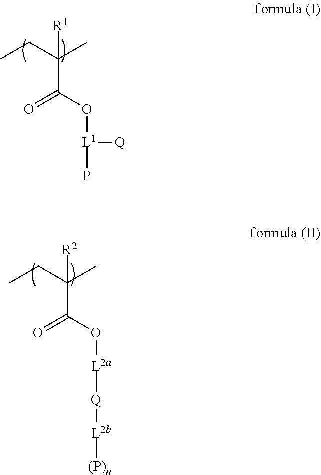

(In general formulas (I) and (II), R¹ and R² each indicate a hydrogen atom, a methyl group, or a hydroxymethyl group. L¹ indicates a trivalent linking group, L^{2a} indicates a single bond or a bivalent linking group, and L^{2b} indicates a single bond, a bivalent linking group, or a trivalent linking group. P indicates an ethylenically unsaturated group, Q indicates a hydrophilic group, and n is 1 or 2).

R¹ and R² independently indicate a hydrogen atom, a methyl group, or a hydroxymethyl group. As R¹ and R², the hydrogen atom or the methyl group is preferable, and the methyl group is more preferable.

L¹ indicates a trivalent linking group. The trivalent linking group is an aliphatic group, an alicyclic groups, an aromatic groups, or a trivalent group obtained by combining these, and may include an ester bond, an ether bond, a sulfide bond, and a nitrogen atom. The carbon number of the trivalent linking group is preferably 1 to 9.

L^{2a} indicates a single bond or a bivalent linking group. The bivalent linking group is an alkylene group, a cycloalkylene group, an arylene group, or a bivalent group obtained by combining these, and may include an ester bond, an ether bond, and a sulfide bond. The carbon number of the bivalent linking group is preferably 1 to 8.

L^{2b} indicates a single bond, a bivalent linking group, or a trivalent linking group. The bivalent linking group indicated by L^{2b} is the same as the bivalent linking group indicated by L^{2a}, and the preferable range is also the same. The trivalent linking group indicated by L^{2b} is the same as the trivalent linking group indicated by L¹, and the preferable range is also the same.

P indicates an ethylenically unsaturated group. The ethylenically unsaturated group indicated by P is the same as the ethylenically unsaturated group exemplified above, and the preferable ethylenically unsaturated group is also the same. Also, Q indicates a hydrophilic group. The hydrophilic group indicated by Q is the same as the hydrophilic group exemplified above, and the preferable hydrophilic group is also the same.

n is 1 or 2, and is preferably 1.

Note that L¹, L^{2a}, and L^{2b} do not include an ethylenically unsaturated group and a hydrophilic group.

The poly(meth)acrylate compound (acrylic resin) may further include repeating units represented by general formula (III) and/or general formula (IV) below.

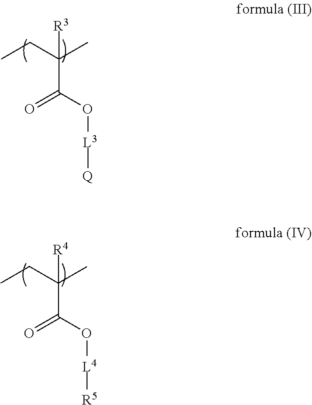

(In general formulas (III) and (IV), R³ and R⁴ each indicate a hydrogen atom, a methyl group, or a hydroxymethyl group. L³ and L⁴ each indicate a single bond or a bivalent linking group. Q indicates a hydrophilic group. R⁵ indicates an aliphatic group with 1 to 12 carbon atoms, an alicyclic group with 3 to 12 carbon atoms, or an aromatic group with 6 to 12 carbon atoms).

R³ and R⁴ each indicate a hydrogen atom, a methyl group, or a hydroxymethyl group. As R³ and R⁴, the hydrogen atom or the methyl group is preferable, and the methyl group is more preferable.

L³ and L⁴ each indicate a single bond or a bivalent linking group. The bivalent linking group indicated by each of L³ and L⁴ is the same as the bivalent linking group indicated by L^{2a} in general formula (I), and the preferable range is also the same.

Q indicates a hydrophilic group. The hydrophilic group indicated by Q is the same as the hydrophilic group exemplified above, and the preferable hydrophilic group is also the same.

R⁵ indicates an aliphatic group with 1 to 12 carbon atoms, an alicyclic group, or an aromatic group. Examples of the aliphatic group with 1 to 12 carbon atoms are alkyl groups with 1 to 12 carbon atoms (for example, a methyl group, an ethyl group, a propyl group, an isopropyl group, a butyl group, an isobutyl group, a t-butyl group, a pentyl group, an isopentyl group, a neopentyl group, a hexyl group, a heptyl group, an octyl group, a 2-ethylhexyl group, a 3,3,5-trimethylhexyl group, an isooctyl group, a nonyl group, an isononyl group, a decyl group, an isodecyl group, an undecyl group, and a dodecyl group). Examples of the alicyclic group with 3 to 12 carbon atoms are cycloalkyl groups with 3 to 12 carbon atoms (for example, a cyclopentyl group, a cyclohexyl group, a norbornyl group, an isobornyl group, an adamantyl group, and a tricyclodecanyl group). Examples of the aromatic group with 6 to 12 carbon atoms are a phenyl group, a naphthyl group, and a biphenyl group. In particular, the phenyl group and the naphthyl group are preferable. The aliphatic group, the alicyclic group, and the aromatic group may have a substituent group.

Detailed examples of an acrylic resin usable in this embodiment will be described below. Note that in the following detailed example, x indicates 0 to 50 mol %, y indicates 0 to 50 mol %, and z indicates 20 to 100 mol %.

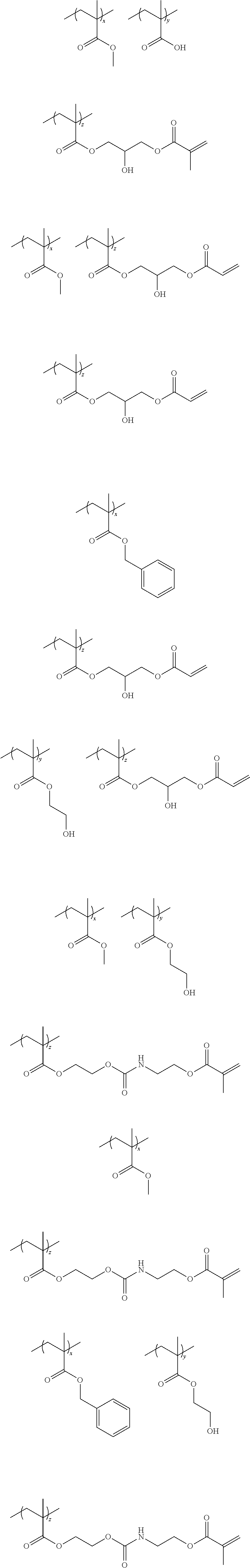

Another example of the compound (A) usable in this embodiment is a compound whose main chain includes an aromatic ring. An example of the compound (A) including an aromatic ring is a compound whose main chain is formed by an aromatic ring and an alkylene group, and the main chain has a structure in which benzene rings and methylene rings are alternately bonded. The compound (A) preferably has a reactive group in the side chain, more preferably has an (meth)acryloyl group in the side chain, and more preferably has an acryloyl group in the side chain.

The compound (A) whose main chain includes an aromatic ring is preferably a polymer mainly containing a structural unit represented by general formula (A) below, and more preferably a polymer in which the content of the structural unit represented by general formula (A) below is 90 mol % or more.

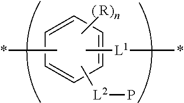

(In general formula (A), R is an alkyl group, L¹ and L² are each a bivalent linking group, and P is a polymerizable group. n is an integer of 0 to 3).

R is preferably an alkyl group with 1 to 5 carbon atoms, and more preferably a methyl group. L1 is preferably an alkylene group, more preferably an alkylene group with 1 to 3 carbon atoms, and more preferably “—CH₂—”. L² is preferably “—CH₂—”, “—O—”, “—CHR(R is a substituent group)-”, and a bivalent linking group formed by combining two or more of these. R is preferably an OH group. P is preferably a (meth)acryloyl group, and more preferably an acryloyl group. n is preferably an integer of 0 to 2, and more preferably 0 or 1.

Still another example of the compound (A) usable in this embodiment is an epoxy poly(meth)acrylate compound. Also, as the compound (A), a compound described in, for example, paragraphs to of Japanese Patent Laid-Open No. 2009-503139 is usable, and the contents can be incorporated in this specification by reference.

Of the above-described compounds (A), a compound having a functional group with a high bondability with the base material is preferable. The functional group with a high bondability with the base material is selected from a hydroxyl group, a carboxyl group, a thiol group, an amino group, an epoxy group, and a (block) isocyanate group and the hydroxyl group or the carboxyl group is particularly preferable.

The compound (A) may be a low-molecular compound or a polymer, and a polymer is preferable. The molecular weight is normally 200 or more and 100,000 or less, preferably 500 or more and 50,000 or less, and further preferably 1,000 or more and 10,000 or less. In a case where the molecular weight of the compound (A) is 200 or less, it may volatilize in a baking step. In a case where the molecular weight is 100,000 or more, bubbles may remain in a spin coating step.

Note that the compound (A) may be formed by one type of a compound, or may be formed by a plurality of types of compounds.

### <Cross-Linker (B)>

The cross-linker (B) according to this embodiment is a compound including, in one molecule, at least a total of five groups of one or both of an alkoxyalkyl group and an alkylol group (to be referred to as “functional groups a” hereinafter).

The functional group a included in the cross-linker (B) according to this embodiment is a functional group that reacts with a hydroxyl group or a carboxyl group included in the compound (A) in an adhesion layer forming step to be described later. As a result, a bond is generated between the compound (A) and the cross-linker (B). The cross-linker (B) includes a plurality of functional groups a in one molecule and can therefore generate bonds with a plurality of compounds (A). When the cross-linker (B) generates bonds with the plurality of compounds (A), a structure (crosslinked structure) in which the compounds of the adhesion layer 101 cross-link can be formed.

The reaction between the functional group a included in the cross-linker (B) according to this embodiment and the hydroxyl group or the carboxyl group included in the compound (A) preferably occurs in the heating process in the adhesion layer forming step to be described later.

When the adhesion layer 101 having a crosslinked structure is formed, the amount of the liberated unreacted compound (A) or cross-linker (B), which is not connected to the base material 102, can be reduced. Thus, the film strength of the adhesion layer 101 can be improved.

In a case where the unreacted compound (A) or cross-linker (B) in a liberated state exists in the adhesion layer 101, in the arranging step of the curable composition 103 to be described later, these compounds may elute into the curable composition 103. As a result, the composition of the curable composition 103 changes, and the property of the curable composition 103 thus changes. This may cause, for example, a pattern peeling defect in the cured film 109 obtained by curing the curable composition 103.

On the other hand, in a case where the adhesion layer forming composition 100 according to this embodiment is used, the amount of the liberated unreacted compound (A) or cross-linker (B) in the adhesion layer 101, which is not connected to the base material 102, can be made much smaller than before. It is therefore possible to greatly suppress elution of the compound (A) or the cross-linker (B) into the curable composition 103 in the arranging step of the curable composition 103. As a result, occurrence of the above-described pattern peeling defect in the cured film 109 can be suppressed.

Also, the functional group a included in the cross-linker (B) may generate a chemical bond such as a covalent bond, an ionic bond, a hydrogen bond, or an intermolecular force or an interaction with a functional group that exists on the surface of the base material 102. For example, in a case where a base material including a hydroxyl group such as a silanol group is used as the base material 102, dealcoholation reaction occurs between the alkoxyalkyl group and the silanol group. As a result, a covalent bond can be formed between the cross-linker (B) and the base material 102. This can improve the adhesion between the adhesion layer 101 and the base material 102.

Furthermore, the cross-linker (B) is preferably a compound represented by general formula (1) below.

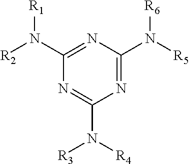

In general formula (1), R₁ to R₆ independently indicate one of a hydrogen atom, an alkyl group, an alkoxyalkyl group, and an alkylol group. However, at least five of R₁ to R₆ are an alkoxyalkyl group or an alkylol group.

The compound represented by general formula (1) above is a derivative of melamine having a triazine ring at the center of the structure. That is, the compound represented by general formula (1) has a structure in which nitrogen atoms are bonded to the 2-, 4-, and 6-positions of 1,3,5-triazine. Also, the compound represented by general formula (1) has five or six functional groups a. That is, the compound represented by general formula (1) above has many functional groups a as compared to urea compounds such as a derivative of glycoluril.

The type of the alkoxyalkyl group or the alkylol group included in the cross-linker (B) is not particularly limited. As the alkoxyalkyl group, a methoxymethyl group is preferable, and as the alkylol group, a methylol group is preferable. When a functional group with a small formula weight is used as the alkoxyalkyl group or the alkylol group, the crosslinking density per unit mass in the adhesion layer 101 can be improved. As a result, the film strength of the adhesion layer 101 can be improved.

Detailed examples of the cross-linker (B) are pentamethoxymethylmelamine, hexamethoxymethylmelamine, (hydroxymethyl)pentakis(methoxymethyl) melamine, hexaethoxymethyl melamine, hexabutoxymethyl melamine, pentamethylol melamine, and hexamethylol melamine. The cross-linker (B) can contain at least one substance selected from these, but the present invention is not limited to this.

As the cross-linker (B), a urea compound may be applied. Detailed examples of the urea compound are methylated urea cross-linkers such as tetrakis(methoxymethyl)glycoluryl, 4,5-dimethoxy-1,3bis(methoxymethyl)imidazolidin-2-one, tetrakis(butoxymethyl)glycoluryl, tetrakis(ethoxymethyl)glycoluryl, tetrakis(isopropoxymethyl)glycoluryl, tetrakis(acyloxymethyl)glycoluryl, and tetrakis(hexylmethyl)glycoluryl.

As commercially available urea compounds, NIKALAC MX-270, NIKALAC MX-280, and NIKALAC MX-290 commercially available from SANWA Chemical, Powderlink 1174 commercially available from American Cyanamid Co., and Cymel 1170 commercially available from Cytec Industries can preferably be used.

Monomers of the above-described resins can also be used. Examples are the following compounds and dimethoxymethyl urea.

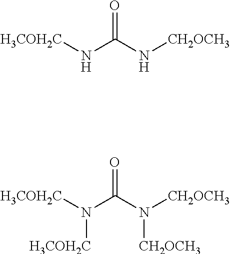

Note that the cross-linker (B) may be formed by one type of a compound, or may be formed by a plurality of types of compounds.

### <Blending Ratio of Compound (A) and Cross-Linker (B)>

In a case where the blending ratio of one of the compound (A) and the cross-linker (B) in the adhesion layer forming composition 100 is extremely small, the crosslinking density of the adhesion layer 101 is low, and the film strength or curability is insufficient. Hence, when the weight fractions of the compound (A) and the cross-linker (B) with respect to the total weight of the adhesion layer forming composition 100 are defined as α and β, respectively, α: β is preferably 1:9 to 9:1, and more preferably 1:5 to 5:1. That is, α/B is preferably 0.11 or more and 9 or less, and more preferably 0.2 or more and 5 or less. Note that the optimum blending ratio changes depending on the number of functional groups, the molecular weights, and the reactivity of the compound (A) and the cross-linker (B). In a case where the blending ratio is substantially set within the above-described range, the curability of the adhesion layer forming composition 100 can be improved.

The blending ratio (the sum of α and β) of the compound (A) and the cross-linker (B) in the adhesion layer forming composition 100 can appropriately be adjusted by the viscosity of the adhesion layer forming composition 100 or the target film thickness of the adhesion layer 101. The sum of α and β is preferably 0.01 or more and 10 or less with respect to the total weight of the adhesion layer forming composition 100, more preferably 0.1 or more and 10 or less, and further preferably 0.1 or more and 7 or less. In a case where the blending ratio of the compound (A) and the cross-linker (B) in the adhesion layer forming composition 100 is set within the above-described range, the viscosity of the adhesion layer forming composition 100 can be lowered, and the film thickness of the formed adhesion layer 101 can be made small.

### <Volatile Solvent (C)>

The adhesion layer forming composition 100 according to this embodiment contains the volatile solvent (C) (to be simply referred to as the “solvent (C)” hereinafter). In a case where the adhesion layer forming composition 100 contains the solvent (C), the viscosity of the adhesion layer forming composition 100 can be lowered. As a result, the applicability of the adhesion layer forming composition 100 to the base material 102 can be improved.

As the solvent (C), a first solvent (C-1) whose boiling point at normal pressure is 80° C. to 200° C. and a second solvent (C-2) whose boiling point at normal pressure is 200° C. to 300° C. may be used in mixture. Alternatively, as the solvent (C), the first solvent (C-1) may be used alone, or the second solvent (C-2) may be used alone.

The first solvent (C-1) is not particularly limited if it is a solvent capable of dissolving the compound (A) and the cross-linker (B), and a solvent whose boiling point at normal pressure is 80° C. to 200° C. is preferable. Also, the first solvent (C-1) is preferably an organic solvent having at least one of a hydroxyl group, an ether structure, an ester structure, and a ketone structure. These solvents are excellent in solubility for the compound (A) and the cross-linker (B) and wettability to the base material 102.

As detailed examples of the solvent usable as the first solvent (C-1) according to this embodiment, a single solvent selected from alcohol solvents such as n-propanol, iso-propanol, n-butanol, iso-butanol, sec-butanol, tert-butanol, n-pentanol, iso-pentanol, 2-methylbutanol, sec-pentanol, tert-pentanol, 3-methoxybutanol, n-hexanol, 2-methylpentanol, sec-hexanol, 2-ethylbutanol, sec-heptanol, 3-heptanol, n-octanol, 2-ethyl hexanol, sec-octanol, 2,6-dimethylheptanol-4, sec-undecyl alcohol, phenol, cyclohexanol, methylcyclohexanol, 3,3,5-trimethylcyclohexanol, diacetone alcohol, ethylene glycol, 1,2-propylene glycol, 2-methyl-2,4-pentanediol, and propylene glycol; ether solvents such as n-butyl ether, 2-ethylhexyl ether, dioxane, dimethyldioxane, 2-methoxyethanol, 2-ethoxyethanol, ethylene glycol diethyl ether, 2-n-butoxyethanol, diethylene glycol monomethyl ether, diethylene glycol diethyl ether, 1-n-butoxy-2-propanol, propylene glycol monomethyl ether, propylene glycol monoethyl ether, propylene glycol monopropyl ether, dipropylene glycol monomethyl ether, and 2-methyltetrahydrofuran; ester solvents such as butyl acetate, ethylene glycol monoethyl ether acetate, ethylene glycol monobutyl ether acetate, and propylene glycol monomethyl ether acetate; ketone solvents such as methyl ethyl ketone, methyl-n-propyl ketone, methyl-n-butyl ketone, diethyl ketone, methyl iso-butyl ketone, methyl-n-pentyl ketone, ethyl-n-butyl ketone, methyl-n-hexyl ketone, di-iso-butyl ketone, cyclohexanone, methylcyclohexanone, 2,4-pentanedione, acetonylacetone, diacetone alcohol, and fenthion; and amide solvents such as diethyl carbonate, amyl acetate, n-propyl acetate, iso-propyl acetate, n-butyl acetate, iso-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, cyclohexyl acetate, methylcyclohexyl acetate, methyl acetoacetate, ethyl acetoacetate, ethylene glycol acetate monomethyl ether, ethylene glycol acetate monoethyl ether, propylene glycol acetate monomethyl ether, propylene glycol acetate monoethyl ether, glycol diacetate, ethyl propionate, n-butyl propionate, iso-amyl propionate, diethyl oxalate, methyl lactate, ethyl lactate, n-butyl lactate, acetic acid solvents such as diethyl malonate, N-methylformamide, N,N-dimethylformamide, N,N-diethylformamide, N,N-dimethylacetamide, and N-methylpropionamide, or a solvent mixture thereof can be used. Of these, propylene glycol monomethyl ether acetate or a solution mixture thereof is particularly preferable in the viewpoint of applicability.

The second solvent (C-2) is not particularly limited if it is a solvent capable of dissolving the compound (A) and the cross-linker (B), and a solvent whose boiling point at normal pressure is 200° C. to 300° C. is preferable. Also, the second solvent (C-2) is preferably an organic solvent having at least one of a hydroxyl group, an ether structure, an ester structure, and a ketone structure. These solvents are excellent in solubility for the compound (A) and the cross-linker (B) and wettability to the base material 102.

As detailed examples of the solvent usable as the second solvent (C-2) according to this embodiment, a single solvent selected from alcohol solvents such as n-nonyl alcohol, n-decanol, sec-tetradecyl alcohol, benzyl alcohol, phenylmethylcarbinol, 1,3-butylene glycol, 2,4-pentanediol, 2,5-hexanediol, 2-ethyl-1,3-hexanediol, diethylene glycol, triethylene glycol, and tripropylene glycol; ether solvents such as n-hexyl ether, 2-n-hexoxyethanol, 2-phenoxyethanol, 2-(2-ethylbutoxy) ethanol, ethylene glycol dibutyl ether, diethylene glycol monoethyl ether, diethylene glycol mono-n-butyl ether, diethylene glycol di-n-butyl ether, diethylene glycol mono-n-hexyl ether, ethoxytriglycol, 1-phenoxy-2-propanol, dipropylene glycol monopropyl ether, and tripropylene glycol monomethyl ether; ketone solvents such as acetophenone; acetic acid solvents such as γ-butyrolactone, γ-valerolactone, benzyl acetate, n-nonyl acetate, diethylene glycol monoethyl ether acetate, diethylene glycol mono-n-butyl ether acetate, dipropylene glycol monomethyl ether acetate, di-n-butyl oxalate, n-amyl lactate, dimethyl phthalate, and diethyl phthalate; and amide solvents such as acetamide, n-methylacetamide, and n-methylpyrrolidone, or a solvent mixture thereof can be used.

As described above, the solvent (C) may contain two types of solvents, that is, the first solvent (C-1) and the second solvent (C-2). In a case where the total mass of the first solvent (C-1) and the second solvent (C-2) is defined as 100 mass parts, the ratio of the second solvent (C-2) is preferably 1 to 50 mass parts, more preferably 2 to 40 mass parts, and further preferably 5 to 25 mass parts. In a case where the mass part of the second solvent (C-2) is set within the above-described range, the in-plane uniformity of the film thickness and the defect density are improved. Note that the solvent (C) may contain three or more types of solvents.

The blending ratio of the solvent (C) according to this embodiment in the adhesion layer forming composition 100 can appropriately be adjusted by the viscosities or applicabilities of the compound (A) and the cross-linker (B) and the film thickness of the adhesion layer 101 to be formed. In a case where the whole adhesion layer forming composition 100 is defined as 100 mass %, the blending ratio (content) of the solvent (C) in the adhesion layer forming composition 100 is preferably 70 mass % or more, more preferably 90 mass % or more, and further preferably 95 mass % or more. The higher the blending ratio of the solvent (C) in the adhesion layer forming composition 100 is, the thinner the film thickness of the adhesion layer 101 to be formed can be. For this reason, the adhesion layer forming composition is suitable as an adhesion layer forming composition for imprint. In a case where the blending ratio of the solvent (C) in the adhesion layer forming composition 100 is less than 70 mass %, it may be impossible to obtain sufficient applicability. Note that the upper limit of the blending ratio of the solvent (C) is not particularly limited, but is preferably 99.9 mass % or less, and more preferably 99.5 mass % or less.

### <Surfactant (D)>

A surfactant is a general term for substances having a hydrophilic group and a hydrophobic group. A numerical value used as an index in selecting a surfactant is an HLB (Hydrophile-Lipophile Balance) value. The HLB value is a value of 1 to 20 representing the balance between hydrophilicity and hydrophobicity in a surfactant. The closer the HLB value is to 1, the higher the hydrophobicity is. The closer the HLB value is to 20, the higher the hydrophilicity is.

In general, a surfactant with an HLB value of 1 to 3 is added as a defoamant, a surfactant with an HLB value of 3 to 6 is added as a W/O emulsifier, and a surfactant with an HLB value of 7 to 9 is added as a wetting agent in many cases. Also, a surfactant with an HLB value of 13 to 15 is added as a detergent, and a surfactant with an HLB value of 15 to 18 is added as a solubilizer in many cases. However, since other additives and the HLB balance of the solvent are also taken into consideration, it is not necessarily so in general.

Here, in a case where defects exist in the adhesion layer 101 itself formed on the base material 102, unfilling defects or film thickness unevenness may occur in the cured film of the curable composition 103 formed on the base material 102 (adhesion layer 101) by the imprint technique. Such a defect in the adhesion layer 101 tends to have a perfect circular shape. Hence, the present inventors estimated, as a result of keen examinations, that the defects were formed by curing the adhesion layer forming composition 100 (solution) in the baking step after spin coating without eliminating bubbles included in it. Hence, in this embodiment, a surfactant with a low HLB is added as a defoamant to the adhesion layer forming composition 100. The defoamant has a property of adhering to a bubble film and forming a nonuniform part in the bubble film, thereby lowering the stability of the bubble film and eliminating bubbles.

The surfactant (D) according to this embodiment is a surfactant with an HLB value of 1 to 5. Thee HLB value in this specification is calculated based on group numbers (see Table 1 below) by the Davies method. More specifically, the HLB value can be calculated by “HLB=7+Σ(group number of hydrophilic group)−n(group number of CH₂ group)”.

### Group Numbers of HLB

| Hydrophilic Group | Group Number |
|---|---|
| —SO₄Na | 38.7 |
| —COOK | 21.1 |
| —COONa | 19.1 |
| >N< (quaternary amine) | 9.4 |
| ester (sorbitan ring) | 6.8 |
| ester (release | 2.4 |
| —COOH | 2.1 |
| —OH | 1.9 |
| —OH (sorbitan ring) | 0.5 |
| —O— | 1.3 |

| Lipophilic Group | Group Number |
|---|---|
| —CH₂— | −0.475 |
| CH₃— | −0.475 |
| ═CH— | −0.475 |

| Derivative Group | Group Number |
|---|---|
| —(CH₂CH₂O)— | +0.33 |
| —(CH—CH₂O)— | −0.15 |
| [symbol] | |

The surfactant (D) according to this embodiment may have an HLB value of 1 to 5, include an acetylene bond in one molecule, and include at least one or more hydroxyl groups. Also, the surfactant (D) according to this embodiment may have an HLB value of 1 to 5, and include at least a benzene ring and an ether bond in one molecule. The surfactant (D) according to this embodiment may have an HLB value of 1 to 5, and include a higher alcohol with 7 or more carbon atoms. Here, the surfactant (D) according to this embodiment preferably contains 1 atm % or less of fluorine atoms and more preferably includes no fluorine atoms.

Examples of the surfactant with an HLB value of 1 to 5 are acetylene-, aromatic-, alcohol-, sorbitan-, Pluronic®-, Si—, and amine-based surfactants. However, the surfactant is not particularly limited to these.

An example of acetylene-based surfactant is 2,4,7,9-tetramethyl-5-decyn-4,7-diol. Detailed examples of products are SURFYNOL DF110D, SURFYNOL 104 series, SURFYNOL 420, OLFINE D-10A, and OLFINE D-10PG manufactured by Nisshin Chemical Industry, and ACETYLENOL E00 manufactured by Kawaken Fine Chemicals.

A detailed example of the aromatic-based surfactant is benzophenone dimethyl ketal.

As the alcohol-based surfactant, alcohols with 7 or more carbon atoms are included as monohydric alcohols, alcohols with 13 or more carbon atoms are included as dihydric alcohols, and alcohols with 17 or more carbon atoms are included as trihydric alcohols. Also, a carbon chain may include a double bond or a triple bond. A carboxyl group, an amino group, an epoxy group, or a (block) isocyanate group may be included. Detailed examples are heptanol, octanol, nonanol, decanol, undecanol, dodecanol, tridecanol, tetradecanol, pentadecanol, cetanol, instearyl glyceryl ether, stearic acid, glyceryl stearate, mono-myristin, decaglyceryl pentastearate, decaglyceryl penta-isostearate, decaglyceryl pentaoleate, ethylene glycol monostearate, propylene glycol monostearate, glyceryl monostearate, polyethylene glycol monostearate, decaglyceryl pentaoleate, glyceryl isostearate, decaglyceryl pentastearate, glycerol monostearate, glycerol monooleate, monoglycerol fatty acid esters, mono- and diglycerides of stearic acid, oleic acid monoglyceride, caprylic acid mono-diglyceride, propylene glycol monostearate, polyglyceryl-2 tetraisostearate, polyglyceryl-10 dodecabehenate, polyglyceryl-4 pentastearate, polyglyceryl-4 pentaoleate, polyglyceryl-2 diisostearate, polyglyceryl-6 polyricinoleate, polyglyceryl-10 decaoleate, polyglyceryl-4 polyricinoleate, polyglyceryl-10-decaesostearate, polyglyceryl-10 deca-stearate, polyglyceryl-5 hexasterate, polyglyceryl-6 pentastearate, polyglyceryl-4 tristearate, polyglyceryl-2 isostearate, polyglyceryl-6 oleate, polyoxyethylene stearyl ether, and polyoxyethylene stearyl ether. Detailed examples of products are NIKKOL MGS-F75V, NIKKOL MGS-BMV, NIKKOL MGS-BV2, NIKKOL MGS-BV2F, NIKKOL MGM, NIKKOL MGS-F50V, NIKKOL Decaglyn 5-SV, NIKKOL Decaglyn 5-ISV, NIKKOL Decaglyn 5-OV, NIKKOL PMS-1CV, NIKKOL EGMS-70, NIKKOL EGMS-70V, NIKKOL MGS-F50VF, NIKKOL Decaglyn 5-OVF, NIKKOL Decaglyn 5-SVF, NIKKOL PMS-1CSEV, NIKKOL MGS-AV, NIKKOL MGS-AMV, NIKKOL MGS-F40V, NIKKOL MGS-TGV, NIKKOL MGIS, NIKKOL SO-15V, NIKKOL SO-15MV, NIKKOL MYS-2V, NIKKOL MYS-2, NIKKOL MYO-2, NIKKOL MYS-NIKKOL MGS-F40VF, NIKKOL DEGS, and NIKKOL GS-6 manufactured by NIKKO CHEMICALS, RHEODOL MS-50, RHEODOL MS-60, RHEODOL MO-60, EXCEL S-95, EXCEL VS-95, EXCEL 0-95R, EXCEL 200, EXCEL 122V, EXCEL P-40, EXCEL P-40S, EXCEL 122V, EXCEL 200, EXCEL 0-95N, EXCEL 0-95F, HOMOTEX PT, HOMOTEX PS-200V, and PENETOL GE-IS manufactured by KAO, S Face IS-204P, SY Glyster DDB-750, SY Glyster PS-3S, SY Glyster PO-3S, S Face IS-202P, SY Glyster CRS-75, SY Glyster DAO-7S, SY Glyster CR-310, S Face IS-1009P, SY Glyster DAS-7S, SY Glyster HB-750, SY Glyster PS-5S, SY Glyster TS-3S, S Face IS-201P, and SY Glyster PO-5S manufactured by Sakamoto Yakuhin, CUTINA GMSV manufactured by BASF, Glyster A-186E-C manufactured by Taiyo Kagaku, SORBON MG-100 manufactured by TOHO Chemical Industry, Peletex 2917H manufactured by MIYOSHI OIL & FAT, Takesurf D-1402 manufactured by TAKEMOTO OIL & FAT, ADEKA TOL PC-1 manufactured by ADEKA, CADENAX GS-90 manufactured by LIION, and BLAUNON SR-702L manufactured by AOKI OIL INDUSTRIAL.

Detailed examples of the sorbitan-based surfactant are sorbitan monostearate, sorbitan distearate, sorbitan distearate, sorbitan monooleate, sorbitan trioleate, sorbitan monostearate, sorbitan monooleate, sorbitan trioleate, sorbitan sesquioleate, sorbitan sesqui-stearate, sorbitan sesqui-isostearate, sorbitan oleate, sorbitan trioleate, sorbitan stearyl ester, sorbitan oleyl ester, and sorbitan monolaurate. Detailed examples of products are IONET S-85, IONET S-80, and IONET S-60V manufactured by Sanyo Chemical Industries, NIKKOL SS-30V, NIKKOL SO-30V, NIKKOL SO-30VF, NIKKOLSO-15VF, NIKKOL SS-15VF, NIKKOLSS-15V, NIKKOL SO-15VF, NIKKOLSS-15VF, NIKKOL SS-15V, NIKKOLSO-10V, NIKKOL SI-15RV, NIKKOLSO-10VF, NIKKOL SS-10VF, and NIKKOLSS-10 MV manufactured by NIKKO CHEMICALS, RHEODOL SP—S10V, RHEODOL SP-20, RHEODOL SP—S30V, RHEODOL SP-010V, RHEODOL SP—O30V, RHEODOL AS-10V, RHEODOL AO-15V, RHEODOL AO-10V, RHEODOL AO-15V, EMASOL S-10V, EMASOL S-30V, EMASOL O-10V, and EMASOL O-30V manufactured by KAO, SORBON S-80, SORBON S-85, and SORBON S-60 manufactured by TOHO Chemical Industry, Takesurf D-935 and Takesurf D-935-T manufactured by TAKEMOTO OIL & FAT, ADEKA ESTOL S-60 and ADEKA ESTOL S-80 manufactured by ADEKA, and BLAUNON P-20 and BLAUNON P-80 manufactured by AOKI OIL INDUSTRIAL.

Detailed examples of the Pluronic®-based surfactant are PE-61 and PE-71 manufactured by Sanyo Chemical Industries.

Detailed examples of Si-based surfactant are PEG-3 dimethicone, PEG-10 dimethicone, PEG/PPG-19/19 dimethicone, PEG/PPG-19/19 dimethicone, PEG-12 dimethicone, PPG-20 crosspolymer, polysilicone-13, lauryl PEG/PPG-18/18 methicone, lauryl PEG-10 tris(trimethylsiloxy) silyl ethyl dimethicone, cetyl diglyceryl tris(trimethylsiloxy) silyl ethyl dimethicone, cetyl PEG/PPG-10/1 dimethicone, PEG-9 polydimethylsiloxyethyl dimethicone, and lauryl PEG-9 polydimethylsiloxyethyl dimethicone. Detailed examples of products are DOWSIL™ ES-5612 Formulation Aid, DOWSILTMBY 11-030 (DOWSIL™ BY 25-337), DOWSILTMBY 22-008 M, DOWSIL™ EL-7040 Hydro Elastomer Blend, DOWSIL™ FZ-2233, DOWSIL™ 5200 Formulation Aid, DOWSILTMES-5300 Formulation Aid, DOWSIL™ ES-5600Silicone Glycerol Emulsifier, and DOWSILTMES-5700 Formulation Aid manufactured by DOW Toray, and KF-6015, KF-6017, KF-6017P, KF-6048, KF-6028, KF-6028P, and KF-6038 manufactured by Shin-Etsu Silicones.

An example of the amine-based surfactant is N,N-bis(2-hydroxyethyl)-N-cyclohexylamine. Detailed examples of products are Peletex 4817 manufactured by MIYOSHI OIL & FAT, and BLAUNON CHA-2P manufactured by AOKI OIL INDUSTRIAL.

The surfactant (D) preferably has a boiling point of 160° C. or more and 300° C. or less at normal pressure. In a case where the boiling point of the surfactant (D) is 160° C. or more, if the adhesion layer forming composition 100 is being supplied onto the base material 102 at room temperature (for example, during spin coating), the surfactant (D) exhibits a defoaming effect of eliminating bubbles in the adhesion layer forming composition 100 without volatilizing. As a result, defects generated in the adhesion layer 101 itself can be reduced. Also, in a case where the boiling point of the surfactant (D) is 300° C. or less, the surfactant (D) volatilizes in the subsequent baking step, and it is possible to avoid impairment to the basic performance of the adhesion layer 101, which should be exhibited in the imprint step.

Detailed examples of the surfactant (D) having a boiling point of 160° C. or more and 300° C. or less at normal pressure are 2,4,7,9-Tetramethyl-5-decyn-4,7-diol (boiling point 253° C.), benzophenonedimethylketal (boiling point=290° C.), heptanol (boiling point=177° C.), octanol (boiling point=195° C.), nonanol (boiling point=212° C.), decanol (boiling point=228° C.), undecanol (boiling point=243° C.), dodecanol (boiling point=258° C.), tridecanol (boiling point=272° C.), tetradecanol (boiling point=263° C.), and pentadecanol (boiling point=299° C.). Detailed examples of products are SURFYNOL 104 series (boiling point=253° C.) and SURFYNOL 420 (boiling point=253° C.) manufactured by Nisshin Chemical Industry, and ACETYLENOL E00 (boiling point=253° C.) manufactured by Kawaken Fine Chemicals.

In a case where the whole adhesion layer forming composition 100 is defined as 100 wt %, the blending ratio (content) of the surfactant (D) in the adhesion layer forming composition 100 is preferably 0.02 mass % or more, more preferably 0.1 mass %, and further preferably 0.5 mass % or more. The higher the blending ratio of the surfactant (D) in the adhesion layer forming composition 100 is, the lesser defects in the adhesion layer 101 are. Hence, this is preferable as the adhesion layer forming composition for imprint. In a case where the blending ratio of the solvent (C) in the adhesion layer forming composition 100 is less than 0.02 mass %, it may be impossible to sufficiently obtain the performance for reducing defects in the adhesion layer 101. Note that the upper limit of the blending ratio of the surfactant (D) is not particularly limited, but is preferably 20 mass % or less, more preferably 10 mass % or less, and particularly preferably 3 mass % or less. In a case where the blending ratio is 20 mass % or more, the density of the adhesion layer 101 obtained by curing the adhesion layer forming composition 100 may be low.

Note that the surfactant (D) may be formed by one type of a compound, or may be formed by a plurality of types of compounds.

### <Another Component (E)>

In addition to the compound (A), the cross-linker (B), the solvent (C), and the surfactant (D) described above, the adhesion layer forming composition 100 according to this embodiment may contain another additive component (E) in accordance with various purposes if it does not impair the effect of the present invention. As the additive component (E), a cross-linker, a polymer component, an antioxidant, or a polymerization inhibitor can be used. When the adhesion layer forming composition 100 is arranged on the base material 102 and then cured while making the solvent (C) volatilize by heating, the film thickness of the adhesion layer 101 formed on the base material 102 can be made thin. Hence, the adhesion layer forming composition 100 according to this embodiment preferably contains no photopolymerization initiator that is added for the purpose of curing the adhesion layer forming composition 100 by light irradiation. This is because in a case where the adhesion layer forming composition 100 contains a photopolymerization initiator, photopolymerization may occur in the process of formation of the adhesion layer 101, the adhesion layer forming composition 100 may be cured before the solvent (C) completely volatilizes, and it may be difficult to reduce the film thickness of the adhesion layer 101.

### <Viscosity of Adhesion Layer Forming Composition>

The viscosity of the adhesion layer forming composition 100 according to this embodiment at 23° C. is preferably 0.5 mPa·s or more and 20 mPa·s or less, more preferably 1 mPa·s or more and 10 mPa·s or less, and further preferably 1 mPa·s or more and 5 mPa·s or less. However, the viscosity of the adhesion layer forming composition 100 at 23° C. can change depending on the types of components such as the compound (A), the cross-linker (B), the solvent (C), the surfactant (D), and the other component (E) added as needed and the blending ratio.

When the viscosity of the adhesion layer forming composition 100 at 23° C. is 20 mPa·s or less, it is possible to improve the applicability of the adhesion layer forming composition 100 to the base material 102 and easily adjust the film thickness of the adhesion layer forming composition 100 on the base material 102.

### <Impurities Mixed in Adhesion Layer Forming Composition>

The adhesion layer forming composition 100 according to this embodiment preferably contains impurities as little as possible. The impurities here means substances other than the compound (A), the cross-linker (B) the solvent (C), the surfactant (D), and the other component (E) added as needed, described above. In a case where the adhesion layer forming composition 100 is used for imprint processing, it is particularly preferable that it contains no particles and solid components. Here, the particles typically indicate a gel or solid granular substance having a particle size (diameter) of several nm to several μm. Hence, in a case where the whole adhesion layer forming composition 100 is defined as 100 mass %, the content of particles whose particle size is larger than 0.2 μm in the adhesion layer forming composition 100 is preferably 0 mass % or more and less than 3 mass %.

Therefore, the adhesion layer forming composition 100 according to this embodiment is favorably obtained through a refining step. A refining step like this is preferably filtration using a filter. More specifically, it is favorable to mix the compound (A), the cross-linker (B), the solvent (C), the surfactant (D), and the other component (E) added as needed, described above, and filtrate the mixture by using, for example, a filter having a pore diameter of 0.001 μm or more and 5.0 μm or less. The filtration is preferably performed using a filter having a pore diameter of 0.001 μm or more and 0.2 μm or less. When performing filtration using a filter, it is further favorable to perform the filtration in multiple stages, or to repetitively perform the filtration a plurality of times. It is also possible to re-filtrate a liquid once filtrated through a filter, or perform filtration by using a plurality of filters having different pore diameters. Examples of the filter for use in filtration are filters made of, for example, a polyethylene resin, a polypropylene resin, a fluorine resin, and a nylon resin, but the filter is not particularly limited.

Impurities such as particles mixed in the adhesion layer forming composition 100 can be removed through the refining step as described above. It is therefore possible to prevent impurities such as particles from causing unexpected defects in the adhesion layer 101 obtained after the adhesion layer forming composition 100 is applied.

Note that when using the adhesion layer forming composition 100 in order to fabricate a circuit board such as a semiconductor integrated circuit to be used as semiconductor element, it is favorable to avoid mixing of impurities (metal impurities) containing metal atoms in the adhesion layer forming composition 100 as much as possible. This is to prevent impurities such as a metal from obstructing the operation of the circuit board. In this case, the concentration of the metal impurities contained in the adhesion layer forming composition 100 is preferably 10 ppm or less, and more preferably 100 ppb or less.

Hence, the adhesion layer forming composition 100 is preferably prepared without coming into contact with a metal in the manufacturing step. That is, when weighing or blending and stirring the raw materials of the compound (A), the cross-linker (B), the solvent (C), the surfactant (D), and the other component (E) added as needed, described above, it is preferable not to use a weighing tool or container made of a metal. Also, in the above-described refining step, filtration is preferably performed using a metal impurity removing filter. As the metal impurity removing filter, filters made of cellulose, diatomaceous earth, and an ion-exchange resin can be used, but these are not particularly limited. The metal impurity removing filters are preferably used after washing. As the washing method, washing using ultrapure water, washing using an alcohol, and washing using the adhesion layer forming composition 100 are preferably executed in this order.

### <Photocurable Composition>

The curable composition 103 arranged (supplied) onto the adhesion layer 101 formed from the adhesion layer forming composition 100 according to this embodiment normally contains a component (F) that is a polymerizable compound, and a component (G) that is a photopolymerization initiator.

### [Component (F): Polymerizable Compound]

The component (F) is a polymerizable compound. Here, in this specification, the polymerizable compound is a compound that reacts with a polymerization factor (for example, a radical) generated from a photopolymerization initiator (component (G)), and forms a film made of a polymer compound (polymer) by a chain reaction (polymerization reaction). Note that the component (F) may be formed by one type of a polymerizable compound, or may be formed by a plurality of types of polymerizable compounds.

An example of the polymerizable compound as the component (F) is a radical polymerizable compound. The radical polymerizable compound is preferably a compound including one or more acryloyl groups or methacryloyl groups, that is, a (meth)acrylic compound. Hence, the polymerizable compound that is the component (F) preferably includes a (meth)acrylic compound. Also, it is more preferable that the main component of the component (F) is a (meth)acrylic compound, and it is most preferable that the component (F) is a (meth)acrylic compound. Note that “the main component of the component (F) is a (meth)acrylic compound” here indicates that the content of the (meth)acrylic compound in the component (F) is 90 wt %.

In a case where the radical polymerizable compound is formed by a plurality of types of compounds each having one or more acryloyl groups or methacryloyl groups, the component (F) preferably contains a monofunctional (meth)acrylate monomer and a polyfunctional (meth)acrylate monomer. This is because in a case where a monofunctional (meth)acrylate monomer and a polyfunctional (meth)acrylate monomer are combined, a cured film having a high strength can be obtained.

Examples of the monofunctional (meth)acrylic compound having one acryloyl group or methacryloyl group are phenoxyethyl (meth)acrylate, phenoxy-2-methylethyl (meth)acrylate, phenoxyethoxyethyl (meth)acrylate, 3-phenoxy-2-hydroxypropyl (meth)acrylate, 2-phenylphenoxyethyl (meth)acrylate, 4-phenylphenoxyethyl (meth)acrylate, 3-(2-phenylphenyl)-2-hydroxypropyl (meth)acrylate, (meth)acrylate of EO-modified p-cumylphenol, 2-bromophenoxyethyl (meth)acrylate, 2,4-dibromophenoxyethyl (meth)acrylate, 2,4,6-tribromophenoxyethyl (meth)acrylate, EO-modified phenoxy (meth)acrylate, PO-modified phenoxy (meth)acrylate, polyoxyethylenenonylphenylether (meth)acrylate, isobornyl (meth)acrylate, 1-adamantyl (meth)acrylate, 2-methyl-2-adamantyl (meth)acrylate, 2-ethyl-2-adamantyl (meth)acrylate, bornyl (meth)acrylate, tricyclodecanyl (meth)acrylate, dicyclopentanyl (meth)acrylate, dicyclopentenyl (meth)acrylate, cyclohexyl (meth)acrylate, 4-butylcyclohexyl (meth)acrylate, acryloylmorpholine, 2-hydroxyethyl (meth)acrylate, 2-hydroxypropyl (meth)acrylate, 2-hydroxybutyl (meth)acrylate, methyl (meth)acrylate, ethyl (meth)acrylate, propyl (meth)acrylate, isopropyl (meth)acrylate, butyl (meth)acrylate, amyl (meth)acrylate, isobutyl (meth)acrylate, t-butyl (meth)acrylate, pentyl (meth)acrylate, isoamyl (meth)acrylate, hexyl (meth)acrylate, heptyl (meth)acrylate, octyl (meth)acrylate, isooctyl (meth)acrylate, 2-ethylhexyl (meth)acrylate, nonyl (meth)acrylate, decyl (meth)acrylate, isodecyl (meth)acrylate, undecyl (meth)acrylate, dodecyl (meth)acrylate, lauryl (meth)acrylate, stearyl (meth)acrylate, isostearyl (meth)acrylate, benzyl (meth)acrylate, 1-naphthyl methyl (meth)acrylate, 2-naphthyl methyl (meth)acrylate, tetrahydrofurfuryl (meth)acrylate, butoxyethyl (meth)acrylate, ethoxydiethyleneglycol (meth)acrylate, polyethyleneglycol mono(meth)acrylate, polypropyleneglycol mono(meth)acrylate, methoxyethyleneglycol (meth)acrylate, ethoxyethyl (meth)acrylate, methoxypolyethyleneglycol (meth)acrylate, methoxypolypropyleneglycol (meth)acrylate, diacetone (meth)acrylamide, isobutoxymethyl (meth)acrylamide, N,N-dimethyl (meth)acrylamide, t-octyl (meth)acrylamide, dimethylaminoethyl (meth)acrylate, diethylaminoethyl (meth)acrylate, 7-amino-3,7-dimethyloctyl (meth)acrylate, N,N-diethyl (meth)acrylamide, and N,N-dimethylaminopropyl (meth)acrylamide, but the compound is not limited to these.

Examples of commercially available products of the abovementioned monofunctional (meth)acrylic compounds are ARONIX M101, M102, M110, M111, M113, M117, M5700, TO-1317, M120, M150, and M156 (manufactured by TOAGOSEI); MEDOL10, MIBDOL10, CHDOL10, MMDOL30, MEDOL30, MIBDOL30, CHDOL30, LA, IBXA, 2-MTA, HPA, and Viscoat #150, #155, #158, #190, #192, #193, #220, #2000, #2100, and #2150 (manufactured by OSAKA ORGANIC CHEMICAL INDUSTRY); Light Acrylate BO-A, EC-A, DMP-A, THF-A, HOP-A, HOA-MPE, HOA-MPL, PO-A, P-200A, NP-4EA, NP-8EA, and Epoxy Ester M-600A (manufactured by KYOEISHA CHEMICAL); KAYARAD TC110S, R-564, and R-128H (manufactured by NIPPON KAYAKU); NK Ester AMP-10G and AMP-20G (manufactured by SHIN-NAKAMURA CHEMICAL); FA-511A, 512A, and 513A (manufactured by Hitachi Chemical); PHE, CEA, PHE-2, PHE-4, BR-31, BR-31M, and BR-32 (manufactured by DKS); VP (manufactured by BASF); and ACMO, DMAA, and DMAPAA (manufactured by Kohjin), but the products are not limited to these.

Examples of a polyfunctional (meth)acrylic compound having two or more acryloyl groups or methacryloyl groups are trimethylolpropane di(meth)acrylate, trimethylolpropane tri(meth)acrylate, EO-modified trimethylolpropane tri(meth)acrylate, PO-modified trimethylolpropane tri(meth)acrylate, EO- and PO-modified trimethylolpropane tri(meth)acrylate, dimethylol tricyclodecane diacrylate, pentaerythritol tri(meth)acrylate, pentaerythritol tetra(meth)acrylate, ethylene glycol di(meth)acrylate, tetraethylene glycol di(meth)acrylate, polyethylene glycol di(meth)acrylate, polypropylene glycol di(meth)acrylate, 1,4-butanediol di(meth)acrylate, 1,6-hexanediol di(meth)acrylate, neopentyl glycol di(meth)acrylate, 1,3-adamantanedimethanol diacrylate, o-xylylene di(meth)acrylate, m-xylylene di(meth)acrylate, p-xylylene di(meth)acrylate, 1,9-nonanediol diacrylate, 1,10-decanediol diacrylate, tris(2-hydoxyethyl)isocyanurate tri(meth)acrylate, tris(acryloyloxy)isocyanurate, bis(hydroxymethyl)tricyclodecane di(meth)acrylate, dipentaerythritol penta(meth)acrylate, dipentaerythritol hexa(meth)acrylate, EO-modified 2,2-bis(4-((meth)acryloxy)phenyl)propane, PO-modified 2,2-bis(4-((meth)acryloxy)phenyl)propane, EO- and PO-modified 2,2-bis(4-((meth)acryloxy)phenyl)propane, but the compound is not limited to these.

Examples of commercially available products of the abovementioned polyfunctional (meth)acrylic compounds are Yupimer UV SA1002 and SA2007 (manufactured by Mitsubishi Chemical); Viscoat #195, #230, #215, #260, #335HP, #295, #300, #360, #700, GPT, and 3PA (manufactured by OSAKA ORGANIC CHEMICAL INDUSTRY); Light Acrylate 4EG-A, 9EG-A, NP-A, DCP-A, BP-4EA, BP-4PA, TMP-A, PE-3A, PE-4A, and DPE-6A (manufactured by KYOEISHA CHEMICAL); A-DCP, A-HD-N, A-NOD-N, A-DOD-N (manufactured by SHIN-NAKAMURA CHEMICAL); KAYARAD PET-30, TMPTA, R-604, DPHA, DPCA-20, -30, -60, and -120, HX-620, D-310, and D-330 (manufactured by NIPPON KAYAKU); ARONIX M208, M210, M215, M220, M240, M305, M309, M310, M315, M325, and M400 (manufactured by TOAGOSEI); and Ripoxy VR-77, VR-60, and VR-90 (manufactured by SHOWA DENKO), but the products are not limited to these.

Note that in the above-described compounds, (meth)acrylate means acrylate or methacrylate having an alcohol residue equal to acrylate. A (meth)acryloyl group means an acryloyl group or a methacryloyl group having an alcohol residue equal to the acryloyl group. PO indicates a propylene oxide, and a PO-modified compound A indicates a compound in which a (meth)acrylic acid residue and an alcohol residue of a compound A bond via the block structure of a propylene oxide group. EO indicates ethylene oxide, and an EO-modified compound B indicates a compound in which a (meth)acrylic acid residue and an alcohol residue of a compound B bond via the block structure of an ethylene oxide group.

### [Component (G): Photopolymerization Initiator]

The component (G) is a photopolymerization initiator. In this specification, the photopolymerization initiator is a compound that senses light having a predetermined wavelength and generates a polymerization factor (radical). More specifically, the photopolymerization initiator is a polymerization initiator (radical generator) that generates a radical by light (infrared light, visible light, ultraviolet light, far-ultraviolet light, X-ray, a charged particle beam such as an electron beam, radiation, or the like). More specifically, the photopolymerization initiator is a polymerization initiator that generates a radical by light having a wavelength of, for example, 150 nm or more and 400 nm or less. Note that the component (G) may be formed by one type of a photopolymerization initiator, or may be formed by a plurality of types of photopolymerization initiators.

Examples of the radical generator are 2,4,5-triarylimidazole dimers that can have substituent groups, such as a 2-(o-chlorophenyl)-4,5-diphenylimidazole dimer, a 2-(o-chlorophenyl)-4,5-di(methoxyphenyl) imidazole dimer, a 2-(o-fluorophenyl)-4,5-diphenylimidazole dimer, and a 2-(o- or p-methoxyphenyl)-4,5-diphenylimidazole dimer; benzophenone derivatives such as benzophenone, N,N′-tetramethyl-4,4′-diaminobenzophenone (Michiler's ketone), N,N′-tetraethyl-4,4′-diaminobenzophenone, 4-methoxy-4′-dimethylaminobenzophenone, 4-chlorobenzophenone, 4,4′-dimethoxybenzophenone, and 4,4′-diaminobenzophenone; □-amino aromatic ketone derivatives such as 2-benzyl-2-dimethylamino-1-(4-morpholinophenyl)-butanone-1,2-methyl-1-[4-(methylthio)phenyl]-2-morpholino-propane-1-one; quinones such as 2-ethylanthraquinone, phenanthrenequinone, 2-t-butylanthraquinone, octamethylanthraquinone, 1,2-benzanthraquinone, 2,3-benzanthraquinone, 2-phenylanthraquinone, 2,3-diphenylamthraquinone, 1-chloroanthraquinone, 2-methylanthraquinone, 1,4-naphtoquinone, 9,10-phenanthraquinone, 2-methyl-1,4-naphtoquinone, and 2,3-dimethylanthraquinone; benzoin ether derivatives such as benzoin methyl ether, benzoin ethyl ether, and benzoin phenyl ether; benzoin derivatives such as benzoin, methyl benzoin, ethyl benzoin, and propyl benzoin; benzyl derivatives such as benzyldimethylketal; acridine derivatives such as 9-phenylacridine and 1,7-bis(9,9′-acrydinyl) heptane; N-phenylglycine derivatives such as N-phenylglycine; acetophenone derivatives such as acetophenone, 3-methylacetophenone, acetophenone benzylketal, 1-hydroxycylohexyl phenylketone, and 2,2-dimethoxy-2-phenyl acetophenone; thioxanthone derivatives such as thioxanthone, diethylthioxanthone, 2-isopropylthioxanthone, and 2-chlorothioxanthone; acylphosphine oxide derivatives such as 2,4,6-trimethylbenzoyldiphenylphosphine oxide, bis(2,4,6-trimethylbenzoyl)phenylphosphine oxide, and bis-(2,6-dimethoxybenzoyl)-2,4,4-trimethylpentylphosphine oxide; oxime ester derivatives such as 1,2-octanedione, 1-[4-(phenylthiol)-,2-(O-benzoyloxime)], ethanone, 1-[9-ethyl-6-(2-methylbenzoyl)-9H-carbazole-3-yl]-, and 1-(O-acetyloxime); and xanthone, fluorenone, benzaldehyde, fluorene, anthraquinone, triphenylamine, carbazole, 1-(4-isopropylphenyl)-2-hydroxy-2-methylprapane-1-one, and 2-hydroxy-2-methyl-1-phenylpropane-1-one, but the radical generator is not limited to these.

Examples of commercially available products of the above-described radical generators are Irgacure 184, 369, 651, 500, 819, 907, 784, and 2959, CGI-1700, -1750, and -1850, CG24-61, Darocur 1116 and 1173, Lucirin TPO, LR8893, and LR8970 (manufactured by BASF), and Ubecryl P36 (manufactured by UCB), but the products are not limited to these.

The blending ratio of the component (G) in the curable composition 103 is preferably 0.01 wt % or more and 10 wt % or less with respect to the whole amount of the component (F), and more preferably 0.1 wt % or more and 7 wt % or less. In a case where the blending ratio of the component (G) in the curable composition 103 is 0.01 wt % or more with respect to the whole amount of the component (F), the curing speed of the curable composition 103 increases, and the reaction efficiency can be made high. Also, in a case where the blending ratio of the component (G) in the curable composition 103 is 10.0 wt % or less with respect to the whole amount of the component (F), deterioration of the mechanical strength of obtained cured films (109 and 110) can be prevented.

### [Another Additive Component (H)]

In addition to the above-described compounds (F) and (G), the curable composition 103 may contain another additive component (H) in accordance with various purposes if it does not impair the effect of the present invention. As the additive component (H), a sensitizer, a hydrogen donor, an internal mold release agent, a surfactant, an antioxidant, a volatile solvent, a polymer component, or a polymerization initiator that is not the component (G) can be used.

The sensitizer is a compound that is properly added for the purpose of promoting the polymerization reaction and improving the reaction conversion rate. An example of the sensitizer is a sensitizing dye. The sensitizing dye is a compound that is excited by absorbing light having a specific wavelength and has an interaction with the component (G). Note that the “interaction” herein described is, for example, energy transfer or electron transfer from the sensitizing dye in the excited state to the component (G).

Practical examples of the sensitizing dye are an anthracene derivative, an anthraquinone derivative, a pyrene derivative, a perylene derivative, a carbazole derivative, a benzophenone derivative, a thioxanthone derivative, a xanthone derivative, a coumarin derivative, a phenothiazine derivative, a camphorquinone derivative, an acridinic dye, a thiopyrylium salt-based dye, a merocyanine-based dye, a quinoline-based dye, a styryl quinoline-based dye, a ketocoumarin-based dye, a thioxanthene-based dye, a xanthene-based dye, an oxonol-based dye, a cyanine-based dye, a rhodamine-based dye, and a pyrylium salt-based dye, but the sensitizing dye is not limited to these. Note that it is possible to use one type of a sensitizer alone or to use two or more types of sensitizers by mixing them.

The hydrogen donor is a compound that reacts with an initiation radical generated from the component (G) or a radical at a polymerization growth end, and generates a radical having higher reactivity. The hydrogen donor is preferably added when the component (G) is a photo-radical generator.

Practical examples of the hydrogen donor as described above are amine compounds such as n-butylamine, di-n-butylamine, tri-n-butylphosphine, allylthiourea, s-benzylisothiuronium-p-toluenesulfinate, triethylamine, diethylaminoethyl methacrylate, triethylenetetramine, 4,4′-bis(dialkylamino)benzophenone, N,N-dimethylamino ethylester benzoate, N,N-dimethylamino isoamylester benzoate, pentyl-4-dimethylamino benzoate, triethanolamine, and N-phenylglycine; and mercapto compounds such as 2-mercapto-N-phenylbenzoimidazole and mercapto propionate ester, but the hydrogen donor is not limited to these. Note that as the hydrogen donor, it is possible to use one type of a compound alone or to use two or more types of compounds by mixing them. The hydrogen donor can also have the function as a sensitizer.

In a case where the curable composition 103 contains a sensitizer or a hydrogen donor as the other additive component (H), the content of each compound is preferably 0.1 wt % or more and 20 wt % or less with respect to the whole amount of the component (F). The content is more preferably 0.1 wt % or more and 5.0 wt % or less, and further preferably 0.2 wt % or more and 2.0 wt % or less. In a case where 0.1 wt % or more of a sensitizer is contained with respect to the whole amount of the component (F), the polymerization promotion effect can more effectively be exhibited. In a case where the content of a sensitizer or a hydrogen donor is 5.0 wt % or less, the molecular weight of a high-molecular compound of a formed cured film can be made sufficiently high. Also, it is possible to suppress a dissolution failure of these component to the curable composition 103 or lowering of the storage stability of the curable composition 103.

An internal mold release agent can be added to the curable composition 103 for the purpose of reducing the interface bonding force between a mold 104 and the cured film 109 obtained by curing the curable composition 103, that is, reducing the mold separation force in a mold separation step (to be described later). In this specification, “internal” means that the mold release agent is added to the curable composition 103 in advance before the arranging step of the curable composition 103. It is possible to use one type of an internal mold release agent alone or to use two or more types of internal mold release agents by mixing them.

As the internal mold release agent, it is possible to use surfactants such as a silicon-based surfactant, a fluorine-based surfactant, and a hydrocarbon-based surfactant. In this embodiment, the internal mold release agent is not polymerizable.

The fluorine-based surfactant includes, for example, a polyalkylene oxide (for example, polyethylene oxide or polypropylene oxide) adduct of alcohol having a perfluoroalkyl group, and a polyalkylene oxide (for example, polyethylene oxide or polypropylene oxide) adduct of perfluoropolyether. Note that the fluorine-based surfactant can have a hydroxyl group, an alkoxy group, an alkyl group, an amino group, or a thiol group in a portion (for example, a terminal group) of the molecular structure.

It is also possible to use a commercially available product as the fluorine-based surfactant. Examples of the commercially available product of the fluorine-based surfactant are MEGAFACE F-444, TF-2066, TF-2067, and TF-2068 (manufactured by DIC); Fluorad FC-430 and FC-431 (manufactured by Sumitomo 3M); Surflon S-382 (manufactured by AGC); EFTOP EF-122A, 122B, 122C, EF-121, EF-126, EF-127, and MF-100 (manufactured by Tochem Products); PF-636, PF-6320, PF-656, and PF-6520 (manufactured by OMNOVA Solutions); UNIDYNE DS-401, DS-403, and DS-451 (manufactured by DAIKIN); and FUTAGENT 250, 251, 222F, and 208G (manufactured by NEOS), but the products are not limited to these.

The internal mold release agent can also be a hydrocarbon-based surfactant. The hydrocarbon-based surfactant includes an alkyl alcohol polyalkylene oxide adduct obtained by adding alkylene oxide having a carbon number of 2 to 4 to alkyl alcohol having a carbon number of 1 to 50.

Examples of the alkyl alcohol polyalkylene oxide adduct are as follows. A methyl alcohol ethylene oxide adduct, a decyl alcohol ethylene oxide adduct, a lauryl alcohol ethylene oxide adduct, a cetyl alcohol ethylene oxide adduct, a stearyl alcohol ethylene oxide adduct, and a stearyl alcohol ethylene oxide/propylene oxide adduct. Note that the terminal group of the alkyl alcohol polyalkylene oxide adduct is not limited to a hydroxyl group that can be manufactured by simply adding polyalkylene oxide to alkyl alcohol. This hydroxyl group can also be converted into another substituent group, for example, a polar functional group such as a carboxyl group, an amino group, a pyridyl group, a thiol group, or a silanol group, or a hydrophobic group such as an alkyl group or an alkoxy group.

A commercially available product can also be used as the alkyl alcohol polyalkylene oxide adduct. Examples of the commercially available product of the alkyl alcohol polyalkylene oxide adduct are polyoxyethylene methyl ether (a methyl alcohol ethylene oxide adduct) (BLAUNON MP-400, MP-550, and MP-1000) manufactured by AOKI OIL INDUSTRIAL, polyoxyethylene decyl ether (a decyl alcohol ethylene oxide adduct) (FINESURF D-1303, D-1305, D-1307, and D-1310) manufactured by AOKI OIL INDUSTRIAL, polyoxyethylene lauryl ether (a lauryl alcohol ethylene oxide adduct) (BLAUNON EL-1505) manufactured by AOKI OIL INDUSTRIAL, polyoxyethylene cetyl ether (a cetyl alcohol ethylene oxide adduct) (BLAUNON CH-305 and CH-310) manufactured by AOKI OIL INDUSTRIAL, polyoxyethylene stearyl ether (a stearyl alcohol ethylene oxide adduct) (BLAUNON SR-705, SR-707, SR-715, SR-720, SR-730, and SR-750) manufactured by AOKI OIL INDUSTRIAL, randomly polymerized polyoxyethylene polyoxypropylene stearyl ether (BLAUNON SA-50/50 1000R and SA-30/70 2000R) manufactured by AOKI OIL INDUSTRIAL, polyoxyethylene methyl ether (Pluriol A760E) manufactured by BASF, and polyoxyethylene alkyl ether (EMULGEN series) manufactured by KAO, but the products are not limited to these.

Of these hydrocarbon-based surfactants, the internal mold release agent is preferably an alkyl alcohol polyalkylene oxide adduct, and more preferably a long chain alkyl alcohol polyalkylene oxide adduct.

In a case where the curable composition 103 contains an internal mold release agent as the other additive component (H), the content of the internal mold release agent is preferably, for example, 0.001 wt % or more and 10 wt % or less with respect to the whole amount of the component (F). The content is more preferably 0.01 wt % or more and 7 wt % or less, and further preferably 0.05 wt % or more and 5 wt % or less. When the content is at least 0.001 wt % or more and 10 wt % or less, the mold separation force reduction effect and filling property are excellent.

The curable composition 103 may contain a volatile solvent as the other additive component (H), but preferably substantially contains no volatile solvent. Here, “substantially contain no solvent” means that a volatile solvent other than a volatile solvent unintentionally contained, such as an impurity, is not contained. That is, for example, the content of the volatile solvent in the curable composition 103 is preferably 3 wt % or less with respect to the whole curable composition 103, and more preferably 1 wt % or less. Note that the volatile solvent here indicates a volatile solvent generally used in the curable composition 103 or a photoresist. That is, the type of the volatile solvent is not particularly limited if it dissolves and evenly disperses each compound of the curable composition 103 and does not react with the compound.

[Temperature when Blending Photocurable Composition]

When preparing the curable composition 103 according to this embodiment, at least the component (F) and the component (G) are mixed and dissolved under a predetermined temperature condition. More specifically, this processing is performed within the range of 0° C. or more and 100° C. or less. This also applies to a case where the other additive component (H) is contained.

### [Viscosity of Photocurable Composition]

The viscosity of each component other than the volatile solvent in the curable composition 103 according to this embodiment at 23° C. is preferably 1 mPa·s or more and 100 mPa·s or less. The viscosity is more preferably 1 mPa·s or more and 50 mPa·s or less, and further preferably 1 mPa·s or more and 20 mPa·s or less.

In a case where the viscosity of the curable composition 103 is 100 mPa·s or less, when bringing the curable composition 103 into contact with the mold 104, time needed to fill the concave portions of the fine pattern on the mold with the curable composition 103 is not long. Also, pattern defects due to a filling failure hardly occur. Also, in a case where the viscosity is 1 mPa·s or more, when applying the curable composition 103 onto the base material 102, application unevenness hardly occurs, and when bringing the curable composition 103 into contact with the mold 104, the curable composition 103 hardly flows from an end portion of the mold 104.

### [Surface Tension of Photocurable Composition]

As for the surface tension of the curable composition 103 according to this embodiment, the surface tension of the mixture of the components other than the solvent is preferably 5 mN/m or more and 70 mN/m or less at 23° C. The surface tension is more preferably 7 mN/m or more and 35 mN/m or less, and further preferably 10 mN/m or more and 32 mN/m or less. Here, in a case where the surface tension is 5 mN/m or more, when bringing the curable composition 103 into contact with the mold 104, time needed to fill the concave portions of the fine pattern on the mold 104 with the curable composition 103 is not long. Also, in a case where the surface tension is 70 mN/m or less, the cured film (109 or 110) obtained by photo-curing the curable composition 103 is a cured film having surface smoothness.

### <Impurities Mixed in Photocurable Composition>

The curable composition 103 according to this embodiment preferably contains impurities as little as possible, like the adhesion layer forming composition 100. Therefore, the curable composition 103 is favorably a composition obtained through a refining step, like the adhesion layer forming composition 100. A refining step like this is preferably filtration using a filter.

When performing filtration using a filter, it is favorable to mix the components (F) and (G) and the other additive component (H) added as needed, described above, and filtrate the mixture by using, for example, a filter having a pore diameter of 0.001 μm or more and 5.0 μm or less. When performing filtration using a filter, is it further favorable to perform the filtration in multiple stages, or to repetitively perform the filtration a plurality of times. It is also possible to re-filtrate a liquid once filtrated through a filter, or perform filtration by using a plurality of filters having different pore diameters. Examples of the filter for use in filtration are filters made of, for example, a polyethylene resin, a polypropylene resin, a fluorine resin, and a nylon resin, but the filter is not particularly limited.

Impurities such as particles mixed in the curable composition 103 can be removed through the refining step as described above. Consequently, it is possible to prevent impurities such as particles from causing pattern defects by forming unexpected unevenness on the cured film 109 obtained after the curable composition 103 is cured.

Note that when using the curable composition 103 in order to fabricate a circuit board such as a semiconductor integrated circuit used in a semiconductor element, it is favorable to avoid mixing of impurities (metal impurities) containing metal atoms in the curable composition 103 as much as possible. This is to prevent the impurities such as a metal from obstructing the operation of the circuit board, like the impurities mixed in the adhesion layer forming composition 100. In this case, the concentration of the metal impurities contained in the curable composition 103 is preferably 10 ppm or less, and more preferably 100 ppb or less.

Hence, the curable composition 103 is preferably prepared without coming into contact with a metal in the manufacturing step. That is, when weighing or blending and stirring the raw materials of the components (F) and (G) and the additive component (H), it is preferable not to use a weighing tool or container made of a metal. Also, in the above-described refining step, filtration is preferably performed using a metal impurity removing filter. As the metal impurity removing filter, filters made of cellulose, diatomaceous earth, and an ion-exchange resin can be used, but these are not particularly limited. The metal impurity removing filters are preferably used after washing. As the washing method, washing using ultrapure water, washing using an alcohol, and washing using the curable composition 103 are preferably executed in this order.

### <Film Forming Method and Article Manufacturing Method>

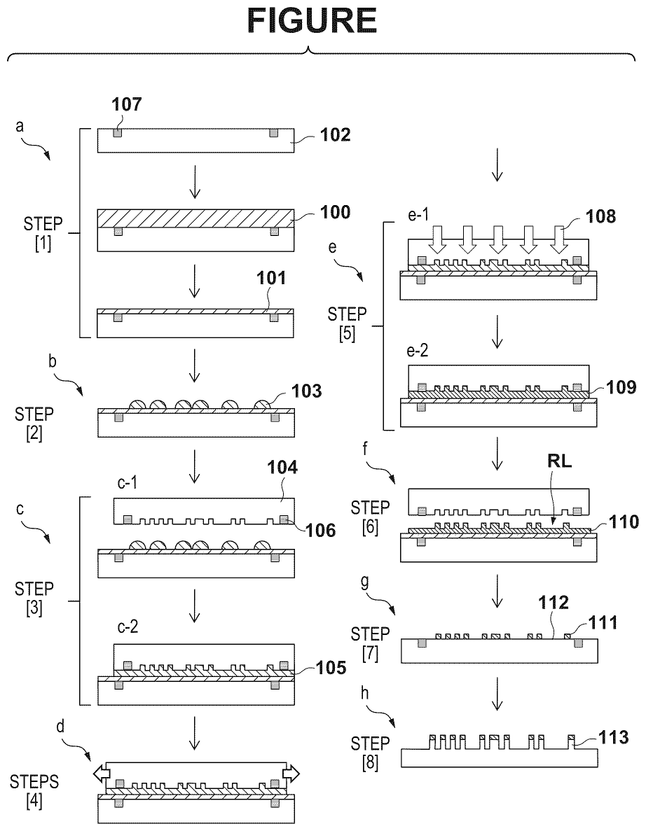

A film forming method and an article manufacturing method according to this embodiment will be described next. FIG. 1 is a view for explaining the film forming method and the article manufacturing method according to this embodiment (a sectional view schematically showing the film forming method). The film forming method according to this embodiment is a method of forming a cured film of a curable composition on a base material (substrate) using a photo-nanoimprint method. In the film forming method according to this embodiment, an example in which a photocurable composition having a property to be cured by light is used will be described. A curable composition having a property to be cured by another energy (for example, heat or an electromagnetic wave) may be used. Also, the film forming method may be executed as a method of forming a cured film having a pattern shape on a base material (that is, a pattern forming method), or may be executed as a method of forming a cured film (for example, a planarized film) having no pattern shape on a base material (that is, a planarized film forming method). The pattern forming method will be exemplified below as the film forming method.

The film forming method according to this embodiment can include an adhesion layer forming step, an arranging step, and a cured film forming step (third step). The adhesion layer forming step is a step (first step) of arranging the above-described adhesion layer forming composition 100 on a base material and forming, on the base material, an adhesion layer that brings the base material and a curable composition into tight contact with each other, and corresponds to a step [1] in FIGURE. The arranging step is a step (second step) of arranging the curable composition on the adhesion layer formed on the base material by the adhesion layer forming step, and corresponds to a step [2] in FIGURE. The cured film forming step is a step (third step) of molding the curable composition using a mold and curing the curable composition, thereby forming a cured film of the curable composition on the base material, and corresponds to steps [3] to [6] in FIGURE. The cured film forming step is also called imprint processing.

The cured film forming step can include a contact step, a curing step, and a mold separation step. The contact step is a step of bringing the curable composition arranged on the base material and the mold into contact with each other, and corresponds to the step [3] in FIGURE. The curing step is a step of curing the curable composition in a state in which the mold and the curable composition on the base material are in contact, and corresponds to the step [5] in FIGURE. In this embodiment, in the curing step, the curable composition is irradiated with light, thereby curing the curable composition. The mold separation step is a step of separating the mold from the cured film of the curable composition obtained by the curing step, and corresponds to the step [6] in FIGURE. Also, the cured film forming step may include an aligning step between the contact step (step [3]) and the curing step (step [5]). The aligning step is a step of aligning the mold and the base material, and corresponds to the step [4] in FIGURE.

The cured film obtained by the film forming method (pattern forming method) according to this embodiment is preferably a film having a pattern with a size of 1 nm or more and 10 mm or less, and more preferably a film having a pattern with a size of 10 nm or more and 100 μm or less. In general, the pattern forming technique for producing a film having a pattern (concave-convex structure) with a nano-size (1 nm or more and 100 nm or less) using light is called a photo-nanoimprint method. Each step of the film forming method will be described below in detail.

### [1] Adhesion Layer Forming Step

In the adhesion layer forming step, as shown by symbol “a” in FIGURE, the adhesion layer 101 mainly containing a polymer compound (polymer) is formed on the base material 102 using the above-described adhesion layer forming composition 100.

The base material 102 that is the target to arrange the curable composition 103 is a substrate or a support body, and an arbitrary base material can be selected in accordance with various purposes. For example, a semiconductor device substrate such as a silicon wafer, aluminum, a titanium-tungsten alloy, an aluminum-silicon alloy, an aluminum-copper-silicon alloy, silicon oxide, or silicon nitride, quartz, glass, an optical film, a ceramic material, a deposition film, a magnetic film, a reflection film, a metal base material such as Ni, Cu, Cr, or Fe, paper, a polymer base material such as a polyester film, a polycarbonate film, or a polyimide film, a TFT array base material, an electrode plate of PDP, a plastic base material, a conductive base material of ITO or a metal, or an insulating base material can be used. However, when processing the base material 102 by etching or the like in a base material processing step (step [8]) to be described later, a semiconductor device substrate such as a silicon wafer is preferably used as the base material 102. As the base material 102, a structure obtained by depositing, on the above-described substrate, one type or a plurality of types of films such as spin-on-glass, an organic matter, a metal, an oxide, and a nitride may be used.

In this embodiment, particularly, as the base material 102, a base material having a hydroxyl group (OH group) such as a silanol group (SiOH group) on the surface is preferably used. Examples of the base material are a silicon wafer, quartz, and glass. It is considered that when a base material having a hydroxyl group on the surface is used, the hydroxyl group provided on the surface of the base material 102 and the functional group of the compound (A) of the adhesion layer forming composition 100 form a chemical bond by a heat treatment. It is considered that even in a case where the cross-linker (B) has an alkoxyalkyl group, it forms a chemical bond by a hydroxyl group.

As a method of applying the adhesion layer forming composition 100 onto the base material 102, for example, an inkjet method, a dip coating method, an air knife coating method, a curtain coating method, a wire bar coating method, a gravure coating method, an extrusion coating method, a spin coating method, and a slit scanning method can be used. The spin coating method is particularly favorable among these methods from the viewpoint of applicability, particularly, film thickness evenness.

After the adhesion layer forming composition 100 is applied (arranged) onto the base material 102, the solvent (C) contained in the adhesion layer forming composition 100 is volatized by drying, thereby forming the adhesion layer 101 on the base material 102. At this time, at the same time as volatilization of the solvent (C), the base material 102 and the compound (A) or the cross-linker (B) are preferably made to react, and the compound (A) and the cross-linker (B) are preferably made to react. This forms a bond between the base material 102 and the adhesion layer 101 and forms a bond between the compound (A) and the cross-linker (B) in the adhesion layer 101. Note that it is assumed that a crosslinked structure is formed by the bond of the compound (A) and the cross-linker (B).

To effectively perform the volatilization and reaction, it is preferable to perform a heat treatment (baking processing) for the base material 102 to which the adhesion layer forming composition 100 is applied. The temperature of the heat treatment can appropriately be selected based on the reactivity between the compound (A) or the cross-linker (B) and the base material 102, the reactivity between the compound (A) and the cross-linker (B), and the boiling points of the compound (A), the cross-linker (B), the solvent (C), the surfactant (D), and the other component (E). The temperature of the temperature is preferably 70° C. or more and 250° C. or less, more preferably 100° C. or more and 220° C. or less, and further preferably 140° C. or more and 220° C. or less. Also, drying of the solvent (C), the reaction between the base material 102 and the compound (A) or the cross-linker (B), and the crosslinking reaction between the compound (A) and the cross-linker (B) may be performed at the same temperature or different temperatures. That is, the reactions may be performed simultaneously or successively.

The film thickness of the adhesion layer 101 formed on the base material 102 by the adhesion layer forming step changes depending on the application purpose, and is, for example, 0.1 nm or more and 100 nm or less, more preferably 0.5 nm or more and 60 nm or less, and further preferably 1 nm or more and 10 nm or less.

When forming the adhesion layer 101 by applying the adhesion layer forming composition 100 onto the base material 102, a second adhesion layer may further be formed on the first adhesion layer 101 using the adhesion layer forming composition 100. This method is called multiple application. Also, the surface of the adhesion layer 101 formed on the base material 102 is preferably as flat as possible. The roughness of the surface is preferably 1 nm or less.

By the adhesion layer forming step, a multilayered body including the base material 102 and the polymer layer (adhesion layer 101) stacked on the base material 102 can be formed. As described above, the polymer layer takes a crosslinked structure by the reaction between the alkoxyalkyl group or alkylol group of the cross-linker (B) and the hydroxyl group or carboxyl group of the compound (A).

### [2] Arranging Step

In the arranging step, as shown by symbol “b” in FIGURE, the above-described curable composition 103 is arranged (supplied) onto the adhesion layer 101 formed on the base material 102 by the adhesion layer forming step.

As a method of arranging the curable composition 103 on the base material 102, for example, an inkjet method, a dip coating method, an air knife coating method, a curtain coating method, a wire bar coating method, a gravure coating method, an extrusion coating method, a spin coating method, and a slit scanning method can be used. In the photo-nanoimprint method, the inkjet method is particularly favorable among these methods. When the inkjet method is used, the curable composition 103 can be arranged (supplied) as a plurality of droplets onto the adhesion layer 101. Here, the film thickness of the liquid film (target shape transfer layer) of the curable composition 103 formed between the mold 104 and the base material 102 by the contact step to be described later changes depending on the application purpose, and is, for example, 0.01 μm or more and 100.0 μm or less. Hence, in the arranging step, the curable composition 103 in a liquid form is arranged on the adhesion layer 101 such that the liquid film obtains a desired film thickness.

### [3] Contact Step

In the contact step, as shown by symbol “c” in FIGURE, the mold 104 is brought into contact with the curable composition 103 arranged on the adhesion layer 101 in the arranging step (as shown by symbol “c-1” in FIGURE). On the surface of the mold 104, a concave-convex pattern (fine pattern) is formed as an original pattern used to transfer the pattern shape to the liquid film of the curable composition 103 (the cured film after the curing step). Thus, the concave portions of the concave-convex pattern formed on the surface of the mold 104 are filled with (a part of) the curable composition 103, and a liquid film 105 of the curable composition 103 is formed in the concave portions and between the mold 104 and the base material 102 (as shown by symbol “c-2” in FIGURE).

The mold 104 is preferably made of a light-transmitting material in consideration of the subsequent curing step. Favorable examples of the type of the material forming the mold 104 are glass, quartz, PMMA, a photo-transparent resin such as a polycarbonate resin, a transparent metal deposition film, a soft film such as polydimethylsiloxane, a photo-cured film, and a metal film. Note that when using the photo-transparent resin as the type of the material forming the mold 104, a resin that does not dissolve in components contained in the curable composition 103 needs to be selected. Quartz is particularly favorable as the type of the material forming the mold 104 because the thermal expansion coefficient is small and pattern distortion is small.

The concave-convex pattern (fine pattern) formed on the surface of the mold 104 preferably has a pattern height of 4 nm or more and 200 nm or less and an aspect ratio of 1 or more and 10 or less. The pattern height can be defined as the distance (height) between the upper surface of a convex portion and the bottom surface of a concave portion in the concave-convex pattern of the mold 104.

A surface treatment may be performed on the mold 104 before performing this step (contact step) of bringing the curable composition 103 and the mold 104 into contact with each other in order to improve the releasability of the surface of the mold 104 from the cured film of the curable composition 103 in the mold separation step to be described later. As a method of surface treatment, a method of forming a mold release agent layer by applying a mold release agent to the surface of the mold 104 can be used.

Examples of the mold release agent to be applied on the surface of the mold 104 are a silicon-based mold release agent, a fluorine-based mold release agent, a hydrocarbon-based mold release agent, a polyethylene-based mold release agent, a polypropylene-based mold release agent, a paraffine-based mold release agent, a montane-based mold release agent, and a carnauba-based mold release agent. It is also possible to suitably use a commercially available coating-type mold release agent such as Optool DSX manufactured by Daikin. Note that it is possible to use one type of a mold release agent alone or two or more types of mold release agents together. Of these mold release agents, fluorine-based and hydrocarbon-based mold release agents are particularly favorable.

In the contact step, the pressure (mold pressure) to be applied to the curable composition 103 when bringing the mold 104 into contact with the curable composition 103 is not particularly limited. Normally, the pressure is 0 MPa or more and 100 MPa or less. Particularly, the pressure is preferably 0 MPa or more and 50 MPa or less, more preferably 0 MPa or more and 30 MPa or less, and further preferably 0 MPa or more and 20 MPa or less.

In the contact step, the time to bring the mold 104 into contact with the curable composition 103 is not particularly limited. Normally, the time of 0.1 sec or more and 600 sec or less, preferably 0.1 sec or more, and 300 sec or less, more preferably 0.1 sec or more and 180 sec or less, and particularly preferably 0.1 sec or more and 120 sec or less.

The contact step can be performed in any of a normal air atmosphere, a reduced-pressure atmosphere, and an inert-gas atmosphere. However, the reduced-pressure atmosphere or the inert-gas atmosphere is favorable because it is possible to prevent the influence of oxygen or water on the curing reaction. Practical examples of an inert gas to be used when performing the contact step in the inert-gas atmosphere are nitrogen, carbon dioxide, helium, argon, various freon gases, and gas mixtures thereof. When performing the contact step in a specific gas atmosphere including a normal air atmosphere, a favorable pressure is 0.0001 atm or more and 10 atm or less.

The contact step may also be performed in an atmosphere containing a condensable gas (to be referred to as a “condensable gas atmosphere” hereinafter). In this specification, the condensable gas indicates a gas that is condensed and liquified by a capillary pressure generated by the pressure at the time of filling. More specifically, the condensable gas is condensed and liquified when the concave portions of the concave-convex pattern formed on the mold 104 and the gap between the mold 104 and the base material 102 or the adhesion layer 101 are filled with the gas in the atmosphere together with (a part of) the liquid film 105. Before the curable composition 103 and the mold 104 come into contact with each other in the contact step (as shown by symbol “c-1” in FIGURE), the condensable gas exists as a gas in the atmosphere. In a case where the contact step is performed in the condensable gas atmosphere, the gas filled in the concave portions of the concave-convex pattern on the mold 104 is liquified, and bubbles disappear. Hence, an excellent filling property can be obtained. The condensable gas may be dissolved into the curable composition 103.

The boiling point of the condensable gas is not limited if it is equal to or less than the atmosphere temperature in the contact step. The boiling point is preferably −10° C. or more and 23° C. or less, and more preferably 10° C. or more and 23° C. or less. Within this range, the filling property is more excellent. The vapor pressure of the condensable gas at the atmosphere temperature in the contact step is not limited if it is equal to or less than the mold pressure in the contact step, and is preferably 0.1 to 0.4 MPa. Within this range, the filling property is more excellent. In a case where the vapor pressure at the atmosphere temperature is higher than 0.4 MPa, there is a tendency that the effect of eliminating bubbles cannot sufficiently be obtained. On the other hand, in a case where the vapor pressure at the atmosphere temperature is lower than 0.1 MPa, the pressure needs to be reduced, and there is a tendency that the apparatus configuration of the apparatus (an imprint apparatus or planarization apparatus) that employs the film forming method according to this embodiment is complex. The atmosphere temperature in the contact step is not particularly limited, and is preferably 20° C. or more and 25° C. or less.

Detailed examples of the condensable gas are freons such as chlorofluorocarbons (CFC) such as trichlorofluoromethane, fluorocarbons (FC), hydrochlorofluorocarbons (HCFC), hydrofluorocarbon (HFC) such as 1,1,1,3,3-Pentafluoropropane (CHF₂CH₂CF₃, HFC-245fa, and PFP), and hydrofluoroether (HFE) such as pentafluoroethyl methyl ether (CF₃CF₂OCH₃, and HFE-245mc), but the condensable gas is not limited to these.

Of these, from the viewpoint of excellent filling property at the atmosphere temperature of 20° C. to 25° C. in the contact step, 1,1,1,3,3-pentafluoropropane (the vapor pressure at 23° C.=0.14 MPa, and boiling point=15° C.), trichlorofluoromethane (the vapor pressure at 23° C.=0.1056 MPa, and boiling point=24° C.), and pentafluoroethyl methyl ether are preferable, and 1,1,1,3,3-pentafluoropropane is particularly preferable from the viewpoint of higher safety.

It is possible to use one type of a condensable gas alone or to use two or more types of condensable gases by mixing them. As the condensable gas, a gas mixture obtained by mixing a noncondensable gas such as air, nitrogen, carbon dioxide, helium, or argon with the condensable gas may be used. The noncondensable gas to be mixed with the condensable gas is preferably helium from the viewpoint of the filling property. Helium can pass through the mold 104. For this reason, when the concave portions of the concave-convex pattern of the mold 104 are filled with the gasses (the condensable gas and helium) in the atmosphere together with (a part of) the liquid film 105 in the contact step, the condensable gas liquifies, and helium passes through the mold 104. Hence, in a case where helium is used as the above-described noncondensable gas, the filling property is excellent.

### [4] Aligning Step

In the aligning step, as shown by symbol “d” in FIGURE, alignment between the mold 104 and the base material 102 is performed. The aligning step is performed before, during and/or after execution of the contact step. In the aligning step, for example, the relative position between the mold 104 and the base material 102 is adjusted such that a mark 106 formed on the mold 104 and a mark 107 formed on the base material 102 obtain a target positional relationship. The mark 106 formed on the mold 104 is sometimes called a mold side alignment mark, and the mark 107 formed on the base material 102 is sometimes called a base material side alignment mark.

### [5] Curing Step

In the curing step, as shown by symbol “e” in FIGURE, the curable composition 103 is cured in a state in which the mold 104 and the curable composition 103 (liquid film 105) on the base material are in contact. More specifically, the liquid film 105 formed in the concave portions of the concave-convex pattern of the mold 104 and between the mold 104 and the base material 102 is irradiated with light 108 via the mold 104 (as shown by symbol “e-1” in FIGURE). Thus, the liquid film 105 of the curable composition 103 formed between the mold 104 and the base material 102 is cured by irradiation of the light 108 and changes to the cured film 109 (as shown by symbol “e-2” in FIGURE). Note that the curing step can be performed after alignment between the mold 104 and the base material 102 is performed by the aligning step.

The light 108 to irradiate the curable composition 103 (liquid film 105) can be selected in accordance with the sensitivity wavelength of the curable composition 103. More specifically, the light 108 is preferably properly selected from ultraviolet light, X-ray, and an electron beam each having a wavelength of 150 nm or more and 400 nm or less. The light 108 (irradiation light) to irradiate the curable composition 103 is particularly preferably ultraviolet light. This is so because many compounds commercially available as curing assistants (photopolymerization initiators) have sensitivity to ultraviolet light. Examples of an ultraviolet light source are a high-pressure mercury lamp, an ultrahigh-pressure mercury lamp, a low-pressure mercury lamp, a Deep-UV lamp, a carbon arc lamp, a chemical lamp, a metal halide lamp, a xenon lamp, a KrF excimer laser, an ArF excimer laser, and an F₂ excimer laser. The ultrahigh-pressure mercury lamp is particularly favorable. It is possible to use one light source or a plurality of light sources. The light 108 can be emitted to the entire surface of the liquid film 105 formed between the mold 104 and the base material 102, or to only a partial region thereof.

Irradiation of the light 108 to the mold 104 may be done intermittently for the entire region on the base material 102 a plurality of times, or irradiation may continuously be performed for the entire region. Furthermore, a partial region A may be irradiated with the light 108 in a first irradiation process, and a region B different from the region A may be irradiated with the light 108 in a second irradiation process. The exposure amount of the curable composition 103 in the curing step is preferably 90 mJ/cm² or less, and more preferably 30 mJ/cm² or less.

### [6] Mold Separation Step

In the mold separation step, as shown by symbol “f” in FIGURE, the mold 104 is separated (released) from the cured film 109 of the curable composition 103 formed on the base material 102 by the curing step. Thus, the inverted pattern of the concave-convex pattern of the mold 104 is transferred to the cured film 109 of the curable composition 103, and a cured product pattern 110 of the curable composition 103 having a predetermined pattern shape is formed on the base material 102.

Here, in a case where the contact step is performed in the condensable gas atmosphere, when separating the cured film 109 and the mold 104 in the mold separation step, the condensable gas gasifies along with lowering of the pressure on the interface of contact between the cured film 109 and the mold 104. Hence, there is a tendency that an effect of reducing the separation force (mold separation force) that is a force necessary for separating the cured film 109 and the mold 104 can be obtained.

The method of separating the cured film 109 and the mold 104 is not particularly limited if a part of the cured film 109 is not physically broken in the separation step, and various kinds of conditions are not particularly limited, either. For example, the separation step may be performed by fixing the base material 102 and moving the mold 104 apart from the base material 102. Alternatively, the separation step may be performed by fixing the mold 104 and moving the base material 102 apart from the mold 104. Alternatively, the separation step may be performed by relatively moving the mold 104 and the base material 102 in opposite directions.

By performing a series of steps (manufacturing process) including the steps [1] to [6] described above, the cured film 109 having a desired concave-convex pattern shape (a pattern shape to which the concave-convex pattern of the mold 104 is transferred) can be formed at a desired position on the base material 102. The cured film 109 formed on the base material 102 can also be used as, for example, an optical member (including a case where the cured film is used as one member of an optical member) such as a Fresnel lens or a diffraction grating. In this case, an optical member including at least the base material 102, and the cured film 109 (cured product pattern 110) formed on the base material 102 can be obtained.

In the film forming method according to this embodiment, a repeating unit including the above-described steps [1] to [6] can repetitively be performed a plurality of times on the same base material 102. More specifically, the steps [1] to [6] in the film forming method according to this embodiment can individually be executed for each of a plurality of shot regions on the base material 102. When the repeating unit (shot) including the steps [1] to [6] is repeated a plurality of times, the cured film 109 having a desired concave-convex pattern shape can be formed at each of a plurality of positions (that is, a plurality of shot regions) on the base material 102.

In addition to a forming step of forming the cured film 109 of the curable composition 103 on the base material 102 using the above-described film forming method (the steps [1] to [6]), the article manufacturing method can include a processing step and a manufacturing step. The processing step is a step of processing the base material 102 that has undergone the forming step, and can include, for example, steps [7] and [8] below. The manufacturing step is a step of manufacturing an article from the base material 102 that has undergone the processing step.

### [7] Residual Layer Removing Step

The cured film 109 (cured product pattern 110) formed on the base material 102 after the mold separation step has a pattern shape corresponding to the concave-convex pattern of the mold 104. In some cases, a part of the cured film 109 remains under the concave portions of the pattern shape. The part of the cured film 109 is sometimes called “a residual layer RL”. In the residual layer removing step, as shown by symbol “g” in FIGURE, the residual layer RL of the cured film 109 and the adhesion layer 101 under it are removed. More specifically, the residual layer RL and the adhesion layer 101 are removed such that the surface of the base material 102 under the concave portions of the cured film 109 is exposed. Accordingly, a cured product pattern 111 corresponding to the convex portions of the cured film 109, that is, the cured product pattern 111 having only a desired concave-convex pattern shape (a pattern shape to which the concave-convex pattern of the mold 104 is transferred) can be formed on the base material 102.

As a method of removing the residual layer RL and the adhesion layer 101 under it, for example, the whole region of the cured film 109 is etched such that the residual layer RL and the adhesion layer 101 under it are removed. This can expose the surface of the base material 102 under the concave portions of the cured film 109. When removing the residual layer RL of the cured film 109 and the adhesion layer 101 under it by etching, the detailed method is not particularly limited and, for example, dry etching can be used. For dry etching, a conventionally known dry etching apparatus can be used. A source gas in dry etching is properly selected in accordance with the element composition of the cured film 109 subjected to etching. Halogen gases such as CF₄, C₂F₆, C₃F₈, CCl₂F₂, CCl₄, CBrF₃, BCl₃, PCl₃, SF₆, and Cl₂, gases containing oxygen atoms such as O₂, CO, and CO₂, inert gases such as He, N₂, and Ar, and gases such as H₂ and NH₃ can be used. Note that these gases can be used in mixture at the time of dry etching.

By performing the above-described steps [1] to [7], the desired concave-convex pattern shape (cured product pattern 111) can be obtained at each of a plurality of positions (shot regions) on the base material 102 and an article having the cured product pattern 111 can be obtained. That is, a device component including the base material 102, the adhesion layer 101 formed on the base material 102, and the cured film (cured product pattern 111) with the concave-convex pattern formed on the adhesion layer 101 can be obtained. In the device component, the adhesion layer 101 has a crosslinked structure formed by the compound (A) and the cross-linker (B). Also, in a case where a compound represented by general formula (1) is used as the compound (A), the adhesion layer 101 has, in the structure, a 1,3,5-triazine ring whose 2-, 4-, and 6-positions are substituted by nitrogen atoms and a sulfide bond. That is, the device component is a device component including the base material 102 and the cured film 109 with a concave-convex pattern on the base material 102, and includes an organic layer between the base material 102 and the cured film 109. The organic layer includes a 1,3,5-triazine ring and a sulfide bond.

Furthermore, when processing the base material 102 using the obtained cured product pattern 111, a base material processing step (step [8]) to be described later is performed. On the other hand, an optical component can be obtained using the obtained cured product pattern 111 as an optical member (including a case where the cured product pattern is used as one member of an optical member) such as a diffraction grating or a polarizing plate. In this case, an optical component including at least the base material 102, and the cured product pattern 111 arranged on the base material 102 can be obtained.

### [8] Base Material Processing Step

The cured product pattern 111 having the concave-convex pattern shape obtained by the film forming method according to this embodiment can also be used as, for example, a film for an interlayer dielectric film included in an electronic component such as a semiconductor element. The cured product pattern 111 can also be used as a resist film when manufacturing a semiconductor element. Examples of the semiconductor element here are an LSI, a system LSI, a DRAM, an SDRAM, an RDRAM, and a D-RDRAM, but the semiconductor element is not limited to these.

When the cured product pattern 111 is used as a resist film, processing is performed for a part (a region indicated by reference numeral 112 in FIGURE) of the base material 102 whose surface is exposed by the above-described residual layer removing step (step [7]). This processing can include etching or ion implantation. At this time, the cured product pattern 111 functions as an etching mask or an ion implantation mask. When an electronic member is formed in addition to this, a circuit structure 113 (as shown by symbol “h” in FIGURE) based on the pattern shape of the cured product pattern 111 can be formed on the base material 102. A circuit board used in a semiconductor element can thus be manufactured. In addition, when the circuit board is connected to a circuit control mechanism of the circuit board, or the like, an electronic device such as a display, a camera, or a medical device can be formed.

Similarly, a device component such as the channel structure of an optical component or a microfluidics or the structure of a patterned media can be obtained by performing etching or ion implantation using the cured product pattern 111 as a resist film.

Similarly, an optical component can be obtained by performing etching or ion implantation using the cured product pattern 111 as a mask (resist film).

Alternatively, an imprint mold can be manufactured by etching a quartz substrate that is the base material 102 using the cured product pattern 111. In this case, the quartz substrate that is the base material 102 may directly be etched using the cured product pattern 111 as a mask. Alternatively, a hard mask material layer may be etched using the cured product pattern 111 as a mask, and a quartz substrate may be etched using a pattern made of the thus transferred hard mask material as a mask. Alternatively, a second cured product of a second curable material may be formed in the concave portions of the cured product pattern 111, and a quartz substrate may be etched using the second cured product as a mask.

To etch a part of the base material 102 with an exposed surface using the cured product pattern 111 as a mask, dry etching can be used. For dry etching, a conventionally known dry etching apparatus can be used. A source gas in dry etching is properly selected in accordance with the element composition of a cured film subjected to etching. Halogen gases such as CF₄, CHF₃, C₂F₆, C₃F₈, C₄F₈, CCl₂F₂, CCl₄, CBrF₃, BCl₃, PCl₃, SF₆, and Cl₂, gases containing oxygen atoms such as O₂, CO, and CO₂, inert gases such as He, N₂, and Ar, and gases such as H₂ and NH₃ can be used. Fluorine gases such as CF₄, CHF₃, C₂F₆, C₃F₈, C₄F₈, CCl₂F₂, CBrF₃, and SF₆ are preferable. This is because the curable composition 103 according to this embodiment exhibits high resistance to dry etching using the above-described fluorine gases. Note that these gases can be used in mixture at the time of dry etching.

Here, in this embodiment, etching and ion implantation have been described as the method of processing the base material 102 using the cured product pattern 111 as a mask. However, the present invention is not limited to this. For example, plating processing or the like may be performed in a state in which the cured product pattern 111 is formed on the base material 102. Also, when manufacturing (producing) an article such as a circuit board or an electronic component, the cured product pattern 111 may finally be removed from the processed base material 102, but may be left as a member forming an element.

### EXAMPLES

The present invention will be described below in more detail using examples, but the technical scope of the present invention is not limited to the following examples. Note that “parts” and “%” used below are on a weight basis unless otherwise specified.

### <(1) Confirmation Test of Volatilization Behavior of Surfactant (D) in Baking Process>

The volatilization behavior of a surfactant (D) in the baking process was confirmed by a method to be described below.

### (1-1) Preparation of Adhesion Layer Forming Composition

A compound (A), a cross-linker (B), and a surfactant (D) shown below were dissolved in a volatile solvent (C) such that a weight (%) in Table 1 was obtained. As the volatile solvent (C), propylene glycol monomethyl ether acetate (manufactured by Tokyo Chemical Industry) was used. Next, the obtained solution mixture was filtered using a polyethylene filter with a pore diameter of 0.005 μm. Thus, compositions 1 to 4 that were adhesion layer forming compositions for defoaming effect evaluation were prepared.

### (Compound (A))

(A-1) Carboxylic anhydride-modified cresol novolac epoxy acrylate (manufactured by SHIN-NAKAMURA CHEMICAL, product name: EA-7140) (formula (1))

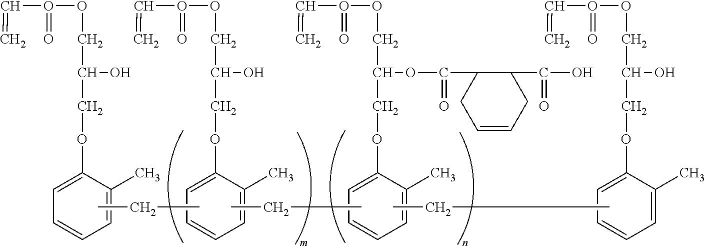

(Cross-Linker (B-1)) (B) 2,4,6-tris [bis(methoxymethyl)amino]-1,3,5-triazine (manufactured by Tokyo Chemical Industry) (formula (2))

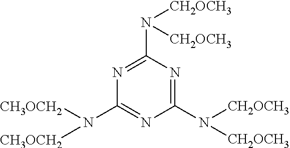

### (Surfactant (D))

(D-1) 2,4,7,9-tetramethyl-5-decyn-4,7-diol (manufactured by Kawaken Fine Chemicals, product name: ACETYLENOL E00, HLB-4) (formula (3))

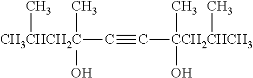

TABLE 1

| | Compound | Cross-linker | Surfactant | Solvent |
|---|---|---|---|---|
| | (A-1) | (B-2) | (D-1) | (C) |
| Composition 1 | 0.2775 | 0.0692 | 0.5 | 99.15 |
| Composition 2 | 0.2775 | 0.0692 | 0.3 | 99.35 |
| Composition 3 | 0.2775 | 0.0692 | 0.1 | 99.55 |
| Composition 4 | 0.2775 | 0.0692 | 0.02 | 99.63 |
| Composition 5 | 0.2775 | 0.0692 | 0 | 99.65 |

### (1-2) Confirmation of Film Thickness Before and After Baking

Each of compositions 1 to 5 was applied to a 2-inch silicon water by spin coating. Each wafer with the adhesion layer forming composition applied was measured using a spectroscopic ellipsometer, and the film thickness before baking was measured. After that, baking was performed under conditions of 220° C. and 90 sec, thereby forming an adhesion layer. Each wafer with the adhesion layer formed thereon was measured using the spectroscopic ellipsometer, and the film thickness after baking was measured. In this example, evaluation was performed using, as a reference, the film thickness of composition 5, after baking, without the surfactant (D) added. A film thickness+0.1 nm or less from composition 5 after baking was evaluated as “A”, a film thickness+0.1 nm or more and 4 nm or less as “B”, a film thickness+4 nm or more and 8 nm or less as “C”, and a film thickness+8 nm or more and 12 nm or less as “D”. The result is summarized in Table 2.

TABLE 2

| | Name of | Film Thickness | Film Thickness |
|---|---|---|---|
| | Composition | Before Baking | After Baking |
| Example 1 | Composition 1 | D | A |
| Example 2 | Composition 2 | C | A |
| Example 3 | Composition 3 | B | A |
| Example 4 | Composition 4 | B | A |
| Example 5 | Composition 5 | — | — |

In each of compositions 1 to 4, the film thickness before baking was thicker than the film thickness of composition 5 after baking. (Examples 1 to 4)

The film thickness of composition 1 before baking was thickest.

### Example 1

In each of compositions 1 to 4, the film thickness after baking was substantially equal to the film thickness of composition 5 after baking. (Examples 1 to 4)

Each of compositions 1 to 4 had a film thickness thicker than the film thickness of composition 5 after baking. Composition 1 with the largest addition amount of the surfactant (D) had the thickest film thickness. This is probably because the added surfactant (D) remained on the wafer even after spin coating.

As for the film thickness after baking, compositions 1 to 4 were substantially equivalent to composition 5. This is supposedly because the surfactant (D) volatilized under the baking conditions of 220° C. and 90 sec.

As described above, it was found that each of the adhesion layers formed by compositions 1 to 4 according to this example contained no surfactant (D). It is therefore considered that since the surfactant (D) added to the adhesion layer volatilizes in the baking process, addition of the surfactant (D) does not affect the adhesion performance of the adhesion layer.

### <(2) Confirmation Test of Defoaming Effect by Addition of Surfactant (D)>

The defoaming effect of the surfactant (D) was evaluated by a method to be described below.

### (2-1) Preparation of Adhesion Layer Forming Composition

A compound (A-1), a cross-linker (B-1), and a surfactant (D-1) were dissolved in a volatile solvent (C) such that a weight (%) in Table 3 was obtained. As the volatile solvent (C), propylene glycol monomethyl ether acetate (manufactured by Tokyo Chemical Industry) was used. Next, the obtained solution mixture was filtered using a polyethylene filter with a pore diameter of 0.005 μm. Thus, compositions 1, 3, 4, and 5 that were adhesion layer forming compositions for defoaming effect evaluation were prepared.

TABLE 3

| | Compound | Cross-linker | Surfactant | Solvent |
|---|---|---|---|---|
| | (A) | (B) | (D-1) | (C) |
| Composition 1 | 0.2775 | 0.0692 | 0.5 | 99.15 |
| Composition 3 | 0.2775 | 0.0692 | 0.1 | 99.55 |
| Composition 4 | 0.2775 | 0.0692 | 0.02 | 99.63 |
| Composition 5 | 0.2775 | 0.0692 | 0 | 99.65 |

### (2-2) Generation of Bubbles

1 L of each of prepared compositions 1, 3, 4, and 5 was measured in a bottle, and bubbles were generated in the liquid of each composition using an aspirator.

### (2-3) Defoaming Effect Confirmation

The bubbles in the liquid generated in (2-2) above were measured by a liquid-borne particle counter (manufactured by RION, product name: KS-18F), thereby confirming the number of generated bubbles. In this example, a case where 1,000 or less bubbles with a particle size of 80 nm or more existed in the liquid was evaluated as “A”, a case where the number of bubbles in liquid was 1,000 or more and 2,000 or less as “B”, and a case where the number of bubbles in liquid was 2,000 or more as “C”. The result is summarized in Table 4.

TABLE 4

| | Name of | Number of Bubbles |
|---|---|---|
| | Composition | in Liquid |
| Example 1 | Composition 1 | A |
| Example 2 | Composition 3 | B |
| Example 3 | Composition 4 | B |
| Comparative | Composition 5 | C |
| Example 1 | | |

In each of compositions 1, 3, and 4, the number of bubbles in liquid was small, and it was smallest in composition 1. (Examples 1 to 3)

On the other hand, in composition 5, the number of bubbles in liquid was larger than in compositions 1, 3, and 4.

### Comparative Example 1

It was supposed that in compositions 1, 3, and 4, the generated bubbles in the liquid were eliminated because the surfactant having the defoaming effect was added. As a result, the numbers of bubbles in liquid were small.

It was also supposed that in composition 1, a high defoaming effect was generated because the addition amount of the surfactant (D) was largest. As a result, the number of bubbles in liquid was smallest.

On the other hand, in composition 5, since the surfactant (D) was not contained, the number of bubbles in liquid was largest.

As described above, it was found that a sufficient defoaming effect was obtained in compositions 1, 3, and 4 according to this example. It is therefore considered that the adhesion layers formed by compositions 1, 3, and 4 according to this example include a smaller number of bubbles on the substrate.

### <(3) Confirmation of Defoaming Effect by HLB Difference>

The defoaming effect by an HLB difference was evaluated next by a method to be described below.

### (3-1) Preparation of Adhesion Layer Forming Composition

A compound (A-1), a cross-linker (B-2), a surfactant (D), and other components (E) shown below were dissolved in a volatile solvent (C-1) such that a weight (%) in Table 5 was obtained. As the volatile solvent (C-1), propylene glycol monomethyl ether acetate (manufactured by Tokyo Chemical Industry) was used.

### (Other Components (E-1))

(E-1) Diethyl phthalate (manufactured by Tokyo Chemical Industry, HLB=7) (formula (4))

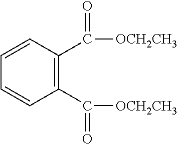 [SMILES: CCOC(=O)c1ccccc1C(=O)OCC]

(E-2) Triethylene glycol (manufactured by Tokyo Chemical Industry, HLB=9) (formula (5))

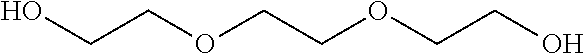

TABLE 5

| | Com- | Cross- | Sur- | Other | Other | Sol- |
|---|---|---|---|---|---|---|
| | pound | linker | factant | component | component | vent |
| | (A-1) | (B-1) | (D-1) | (E-1) | (E-2) | (C) |
| Composition 1 | 0.2775 | 0.0692 | 0.5 | 0 | 0 | 99.15 |
| Composition 6 | 0.2775 | 0.0692 | 0 | 20 | 0 | 79.65 |
| Composition 7 | 0.2775 | 0.0692 | 0 | 0 | 20 | 79.65 |
| Composition 8 | 0.2775 | 0.0692 | 0 | 0 | 0 | 99.65 |

### (3-2) Filtration Using Filter

Next, the obtained solution mixture was filtered using a polyethylene filter with a pore diameter of 0.002 μm.

### (3-3) Confirmation of Number of Bubbles in Liquid in Composition

The compositions produced in (3-2) above were measured by a liquid-borne particle counter (manufactured by RION, product name: KS-18F), thereby confirming the number of bubbles in liquid in each composition. Since bubbles and foreign substances are trapped by the filter, it is supposed that all detected counts indicate bubbles in the liquid generated after the filtration. In this example, a case where 10 or less bubbles with a particle size of 80 nm or more existed in the liquid was evaluated as “A”, a case where the number of bubbles in liquid was 10 or more and 20 or less as “B”, a case where the number of bubbles in liquid was 30 or more and 50 or less as “C”, and a case where the number of bubbles in liquid was 50 or more as “D”. The result is summarized in Table 6.

TABLE 6

| | Name of | Number of Bubbles |
|---|---|---|
| | Composition | in Liquid |
| Example 1 | Composition 1 | A |
| Comparative Example 1 | Composition 6 | B |
| Comparative Example 2 | Composition 7 | C |
| Comparative Example 3 | Composition 8 | D |

In composition 1, the number of bubbles in liquid was smallest.

### Example 1

On the other hand, in compositions 6 to 8, the number of bubbles in liquid was larger than in composition 1. (Comparative Examples 1 to 3)

Foreign substances such as dust and bubbles are trapped at the time of filtration, but a small amount of bubbles are generated by releasing the pressure at the instant of filter passage. The surfactant (D-1) added to composition 1 had HLB=4. It was therefore supposed that the surfactant (D) had a defoaming effect to the adhesion layer forming composition according to this example, and the generated bubbles in the liquid were eliminated. As a result, the number of bubbles in liquid was small.

On the other hand, the other component (E-1) added to composition 6 had HLB=7, and the other component (E-2) added to composition 7 had HLB=9. It was therefore supposed that these had no sufficient defoaming effect to the adhesion layer forming composition according to this example, and the generated bubbles in the liquid were not eliminated. As a result, the number of bubbles in liquid was large.

Since composition 8 did not contain the surfactant (D) and the other components (E), the number of bubbles in liquid was largest.

As described above, it was found that in composition 1 according to this example, since the added surfactant had HLB=4, a sufficient defoaming effect was obtained. It is therefore considered that when an adhesion layer is formed using composition 1 according to the example, generation of bubbles in the liquid can be suppressed.

### <(4) Confirmation of Number of Defects on Wafer by HLB Difference>

The number of defects on a wafer by an HLB difference was evaluated next by a method to be described below.

### (4-1) Formation of Adhesion Layer

Each of compositions 1, 7, and 8 was installed in a spin coater apparatus and applied by spin coating onto a silicon wafer with a diameter of 300 mm. After that, heating was performed under conditions of 220° C. and 90 sec, thereby forming an adhesion layer having a film thickness of 5 nm or less.

### (4-2) Defect Inspection

Each wafer produced in (4-1) above was set in a defect inspection apparatus, and defects on the water were detected. In this example, a case where the number of defects was 100 or less was evaluated as “A”, a case where the number of defects was 100 or more and 500 or less was evaluated as “B”, and a case where the number of defects was 500 or more and 1,000 or less was evaluated as “C”. The result is summarized in Table 7.

TABLE 7

| | Name of Composition | Number of Defects |
|---|---|---|
| Example 1 | Composition 1 | A |
| Comparative Example 1 | Composition 7 | B |
| Comparative Example 2 | Composition 8 | C |

In composition 1, the number of defects was smallest. (Example 1)

On the other hand, in compositions 7 and 8, the number of defects was larger than in composition 1. (Comparative Examples 1 and 2)

The surfactant (D-1) added to composition 1 had HLB=4. It was therefore supposed that the surfactant (D) had a defoaming effect to the adhesion layer forming composition according to this example, and the bubbles generated on the wafer were eliminated. As a result, the number of defects was small.

On the other hand, the other component (E-2) added to composition 7 had HLB=9. It was therefore supposed that this had no sufficient defoaming effect to the adhesion layer forming composition according to this example, and the bubbles generated on the wafer were not eliminated. As a result, the number of defects was large.

Since composition 8 did not contain the surfactant (D), the number of defects was largest.

As described above, it was found that in composition 1 according to this example, since the added surfactant had HLB=4, a sufficient defoaming effect was obtained. It is therefore considered that when an adhesion layer is formed using composition 1 according to the example, generation of bubbles in the liquid can be suppressed, and defects on the wafer can be decreased.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-098730 filed on Jun. 15, 2023, which is hereby incorporated by reference herein in its entirety.

What is claimed is:

1. A layer forming composition used to form an adhesion layer that brings a base material and a curable composition into tight contact with each other, comprising
a surfactant (D) whose HLB value is 1 to 5.

2. The layer forming composition according to claim 1, wherein a boiling point of the surfactant (D) at normal pressure is not less than 160° C. and not more than 300° C.

3. The layer forming composition according to claim 1, wherein the surfactant (D) contains an acetylene bond in one molecule, and includes at least one hydroxyl group.

4. The layer forming composition according to claim 1, wherein the surfactant (D) contains at least a benzene ring and an ether bond in one molecule.

5. The layer forming composition according to claim 1, wherein the surfactant (D) contains a higher alcohol with not less than 7 carbon atoms.

6. The layer forming composition according to claim 1, wherein the surfactant (D) contains not more than 1 atm % of fluorine atoms.

7. The layer forming composition according to claim 1, wherein the surfactant (D) contains no fluorine atom.

8. The layer forming composition according to claim 1, wherein in a case where the whole layer forming composition is defined as 100 mass %, content of the surfactant (D) is not less than 0.02 mass % and not more than 20 mass %.

9. The layer forming composition according to claim 1, wherein
the layer forming composition contains a solvent (C), and
in a case where the whole layer forming composition is defined as 100 mass %, content of the solvent (C) is not less than 70 mass % and not more than 99.5 mass %.

10. The layer forming composition according to claim 1, wherein
the layer forming composition contains a solvent (C),
the solvent (C) contains at least two types of solvents including a first solvent (C-1) whose boiling point at normal pressure is 80° C. to 200° C. and a second solvent (C-2) whose boiling point at normal pressure is 200° C. to 300° C., and
in a case where a total mass of the solvent (C) is defined as 100 mass parts, content of the second solvent (C-2) is 1 to 50 mass parts.

11. The layer forming composition according to claim 1, wherein the layer forming composition contains no photopolymerization initiator.

12. The layer forming composition according to claim 1, wherein in a case where the whole layer forming composition is defined as 100 mass %, content of particles whose particle size is larger than 0.2 μm is less than 3 mass %.

13. The layer forming composition according to claim 1, wherein the layer forming composition contains at least a compound (A) having at least one functional group to be bonded to the base material and at least one polymerizable functional group, a cross-linker (B), and a solvent (C).

14. The layer forming composition according to claim 13, wherein
the cross-linker (B) is a compound represented by a formula below 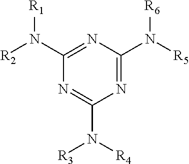
R₁ to R₆ independently indicate one of a hydrogen atom, an alkyl group, an alkoxyalkyl group, and an alkylol group, and at least five of R₁ to R₆ are an alkoxyalkyl group or an alkylol group.

15. The layer forming composition according to claim 13, wherein the cross-linker (B) includes at least one type selected from the group consisting of pentamethoxymethylmelamine, hexamethoxymethylmelamine, (hydroxymethyl)pentakis(methoxymethyl) melamine, hexaethoxymethyl melamine, hexabutoxymethyl melamine, pentamethylol melamine, and hexamethylol melamine.

16. The layer forming composition according to claim 13, wherein the cross-linker (B) is a compound having, in one molecule, at least a total of five groups of at least one of an alkoxyalkyl group and an alkylol group.

17. The layer forming composition according to claim 13, wherein the compound (A) has, in one molecule, at least one of a hydroxyl group, a carboxyl group, a thiol group, an amino group, an epoxy group, and a (block) isocyanate group.

18. The layer forming composition according to claim 13, wherein in a case where weight fractions of the compound (A) and the cross-linker (B) with respect to a total weight of the layer forming composition are defined as α and β, respectively, α/β is not less than 0.11 and not more than 9.

19. The layer forming composition according to claim 13, wherein in a case where weight fractions of the compound (A) and the cross-linker (B) with respect to a total weight of the layer forming composition are defined as α and β, respectively, a sum of α and β is not less than 0.01 and not more than 10.

20. The layer forming composition according to claim 1, wherein the layer forming composition is used for photo-nanoimprint.

21. A film forming method for forming a cured film of a curable composition on a base material, comprising:
arranging, on the base material, a layer forming composition defined in claim 1, thereby forming, on the base material, an adhesion layer that brings the base material and the curable composition into tight contact with each other;
arranging the curable composition on the adhesion layer; and
molding the curable composition using a mold and curing the curable composition, thereby forming the cured film on the base material.

22. The method according to claim 21, wherein the curable composition contains a compound having one of an acryloyl group and a methacryloyl group.

23. The method according to claim 21, wherein the arranging the layer forming composition includes arranging the layer forming composition on the base material having a hydroxyl group on a surface.

24. An article manufacturing method comprising:
forming a cured film of a curable composition on a base material using a film forming method defined in claim 21;
processing the base material that has undergone the forming; and
manufacturing an article from the base material that has undergone the processing.
